(19) United States
(12) Patent Application Publication
(10) Pub. No.: US 2025/0054921 A1
(43) Pub. Date: Feb. 13, 2025

(54) LIGHT EMITTING DEVICE AND ELECTRONIC APPARATUS

(71) Applicants: SONY SEMICONDUCTOR SOLUTIONS CORPORATION, Kanagawa (JP); SONY GROUP CORPORATION, Tokyo (JP)

(72) Inventors: Akira OHMAE, Tokyo (JP); Katsuhiro TOMODA, Kanagawa (JP); Atsushi YASUDA, Kanagawa (JP); Kazuya UEDA, Kanagawa (JP); Goshi BIWA, Tokyo (JP); Hiroki NAITO, Kanagawa (JP); Ippei NISHINAKA, Tokyo (JP)

(73) Assignees: SONY SEMICONDUCTOR SOLUTIONS CORPORATION, Kanagawa (JP); SONY GROUP CORPORATION, Tokyo (JP)

(21) Appl. No.: 18/717,558

(22) PCT Filed: Nov. 18, 2022
(86) PCT No.: PCT/JP2022/042857

§ 371 Date: Jun. 7, 2024

(30) Foreign Application Priority Data
Dec. 14, 2021 (JP) 2021-202667

(51) Int. Cl. H01L 25/075; H01L 23/00; H01L 25/16; H01L 33/62

(52) U.S. Cl. CPC H01L 25/0753; H01L 24/16; H01L 24/48; H01L 25/167; H01L 33/62; H01L 2224/16225; H01L 2224/48225; H01L 2924/12041; H01L 2924/12044; H01L 2924/1426

(57) ABSTRACT

Provided are a light emitting device and an electronic apparatus capable of reducing the number of manufacturing steps and improving space efficiency. A light emitting device includes multiple light emitting element arrays each of which includes multiple light emitting elements, and a main substrate that includes a drive circuit. The multiple light emitting element arrays are provided on the same main substrate.

### TECHNICAL FIELD

The present disclosure relates to a light emitting device and an electronic apparatus.

### BACKGROUND ART

It has been expected to apply a light emitting device including a light emitting element array, such as a semiconductor light emitting element array, to various fields including AR (Augmented Reality), VR (Virtual Reality), and MR (Mixed Reality), with miniaturization and definition improvement of the device.

As this type of light emitting device, there has been proposed such a device which has a structure including multiple light emitting element arrays each having multiple light emitting elements. Such a light emitting device can be manufactured in the following manner. Multiple panels each having a light emitting element array are formed according to emission colors of the light emitting elements and the like. Each of the panels is produced by providing the light emitting element array on a drive substrate in a manner as described in PTL 1. Thereafter, the multiple panels thus formed are arranged in a predetermined layout. In this manner, manufacture of the light emitting device is completed.

### CITATION LIST

### Patent Literature

PTL 1: JP 2003-163368A

### SUMMARY

### Technical Problems

For manufacturing the light emitting device using the technology of PTL 1, it is required to carry out a step of forming the light emitting element array on the drive substrate for each type of the light emitting element array. Moreover, for providing the multiple light emitting element arrays in the predetermined layout, it is required to leave a sufficient space for arranging the multiple drive substrates. Accordingly, there is still room for further improvement over the light emitting device using the technology of PTL 1 in points of reduction of the number of manufacturing steps and enhancement of space efficiency.

The present disclosure has been developed in consideration of the abovementioned points. One object of the present disclosure is to provide such a light emitting device and an electronic apparatus which are capable of reducing the number of manufacturing steps and enhancing space efficiency.

### Solution to Problems

For example, the present disclosure is directed to (1) a light emitting device including multiple light emitting element arrays each of which includes multiple light emitting elements, and a main substrate that includes a drive circuit. The multiple light emitting element arrays are provided on the same main substrate.

The present disclosure may also be applicable to (2) an electronic apparatus including the light emitting device according to (1) described above.

### BRIEF DESCRIPTION OF DRAWINGS

FIG. 1 is a plan diagram depicting a general configuration of a light emitting device according to one example of a first embodiment.

FIG. 2 is a cross-sectional diagram schematically depicting an example of a general configuration of the light emitting device according to the one example of the first embodiment.

FIG. 3 is a cross-sectional diagram schematically depicting a general configuration of a light emitting element included in the light emitting device according to the one example of the first embodiment.

FIG. 4 is a plan diagram for explaining driving of the light emitting device according to the first embodiment.

FIG. 5 is a cross-sectional diagram for explaining operations and advantageous effects of the light emitting device according to the one example of the first embodiment.

FIG. 6A and FIG. 6B are each a cross-sectional diagram schematically depicting an example of a general configuration of a light emitting device according to one example of modification 1 of the first embodiment.

FIG. 7 is a cross-sectional diagram schematically depicting a general configuration of a light emitting element included in the light emitting device according to the one example of modification 1 of the first embodiment.

FIG. 8A and FIG. 8B are each a cross-sectional diagram schematically depicting an example of a general configuration of a light emitting device according to the one example of modification 1 of the first embodiment.

FIG. 9 is a plan diagram schematically depicting an example of a general configuration of a light emitting device according to one example of modification 2 of the first embodiment.

FIG. 10 is a cross-sectional diagram for explaining the light emitting device according to the one example of modification 2 of the first embodiment.

FIG. 11A and FIG. 11B are each a plan diagram schematically depicting an example of a general configuration of a light emitting device according to one example of modification 3 of the first embodiment.

FIG. 12 is a plan diagram schematically depicting an example of a general configuration of a light emitting device according to one example of modification 4 of the first embodiment.

FIG. 13A and FIG. 13B are each a cross-sectional diagram schematically depicting a general configuration of a light emitting device according to one example of modification 5 of the first embodiment.

FIG. 14 is a cross-sectional diagram schematically depicting a general configuration of a light emitting device according to one example of modification 6 of the first embodiment.

FIG. 15 is a cross-sectional diagram schematically depicting a general configuration of a light emitting device according to one example of a second embodiment.

FIG. 16 is a cross-sectional diagram for explaining a light emitting device according to one example of a modification of the second embodiment.

FIG. 17 is a cross-sectional diagram schematically depicting a general configuration of a light emitting device according to one example of a third embodiment.

FIG. 18 is a cross-sectional diagram for explaining a light emitting device according to one example of a modification of the third embodiment.

FIG. 19 is a cross-sectional diagram schematically depicting a general configuration of a light emitting device according to one example of a fourth embodiment.

FIG. 20 is a cross-sectional diagram schematically depicting a general configuration of a light emitting device according to the one example of the fourth embodiment.

FIG. 21 is a front diagram schematically depicting a general configuration of a light emitting device according to one example of a fifth embodiment.

FIG. 22 is a front diagram schematically depicting a general configuration of a light emitting device according to one example of modification 1 of the fifth embodiment.

FIG. 23A is a front diagram schematically depicting a general configuration of a light emitting device according to one example of modification 2 of the fifth embodiment. FIG. 23B is a side diagram schematically depicting a general configuration of the light emitting device according to the one example of modification 2 of the fifth embodiment.

FIG. 24A is a front diagram schematically depicting a general configuration of a light emitting device according to one example of modification 3 of the fifth embodiment. FIG. 24B is a side diagram schematically depicting a general configuration of the light emitting device according to the one example of modification 3 of the fifth embodiment.

FIG. 25A is a front diagram schematically depicting a general configuration of a light emitting device according to one example of modification 4 of the fifth embodiment. FIG. 25B is a side diagram schematically depicting a general configuration of the light emitting device according to the one example of modification 4 of the fifth embodiment.

FIG. 26A is a front diagram schematically depicting a general configuration of a light emitting device according to one example of modification 5 of the fifth embodiment. FIG. 26B is a side diagram schematically depicting a general configuration of the light emitting device according to the one example of modification 5 of the fifth embodiment.

FIG. 27 is a diagram for explaining an example of an electronic apparatus including a light emitting device.

### DESCRIPTION OF EMBODIMENTS

Embodiments and the like according to the present disclosure will be hereinafter described with reference to the drawings. Note that the description will be presented in the following order. In the present description and the drawings, configurations having a substantially identical functional configuration will be given an identical reference sign to omit repetitive explanation.

Note that the description will be presented in the following order.

1. First Embodiment

2. Second Embodiment

3. Third Embodiment

4. Fourth Embodiment

5. Fifth Embodiment

6. Application examples

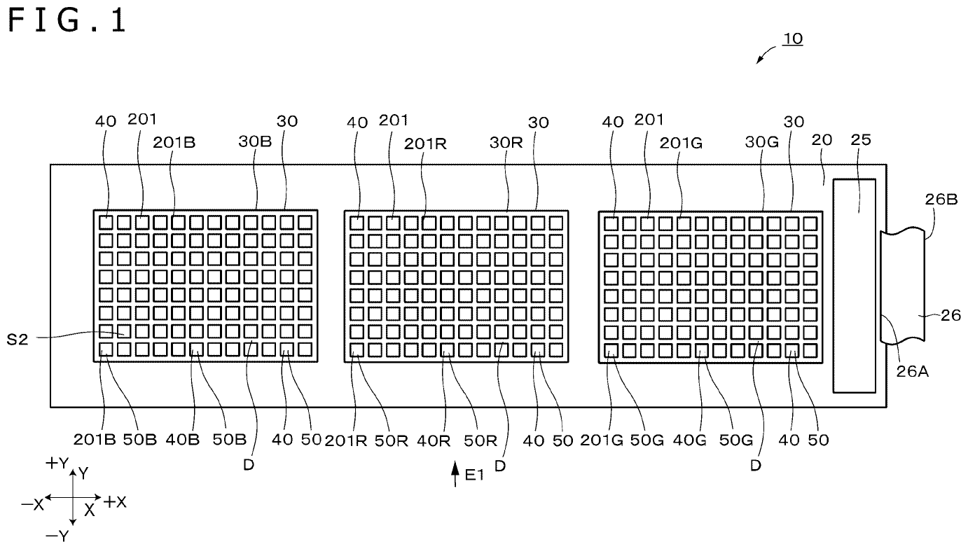

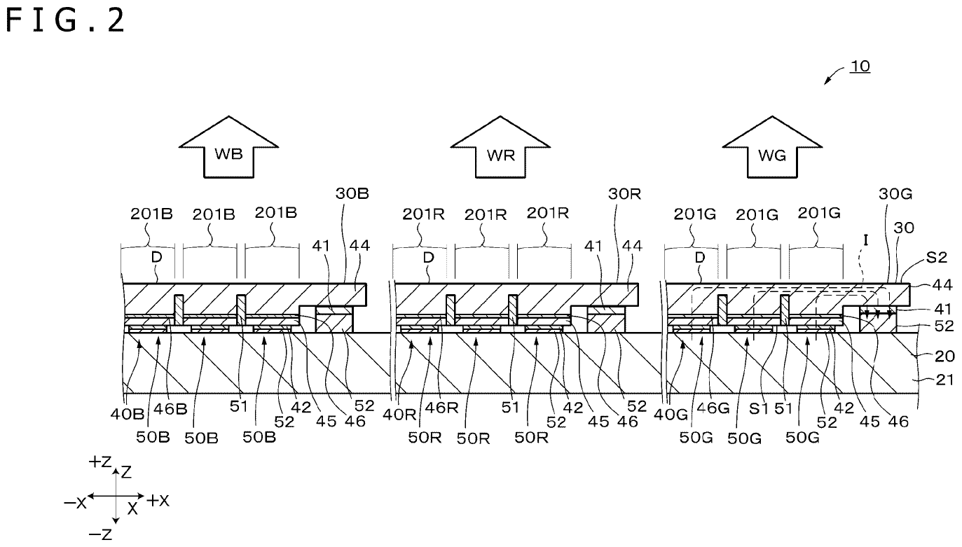

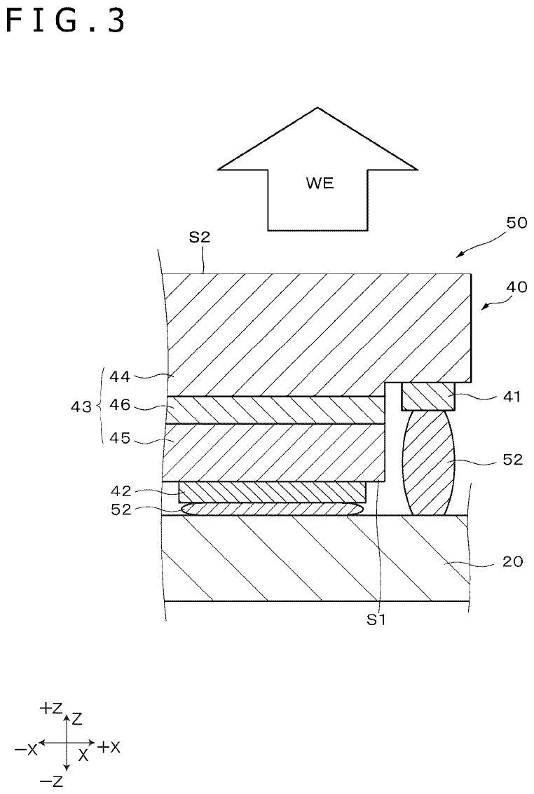

The following description will be presented as preferred specific examples of the present disclosure. Accordingly, details of the present disclosure are not limited to these embodiments and the like. Moreover, front-rear, left-right, up-down, and other directions in the following description are defined in the following manner in consideration of convenience of explanation. However, details of the present disclosure are not restricted by these directions. According to an example in FIG. 1, FIG. 2, and the like, it is assumed that a Z-axis direction corresponds to an up-down direction (a +Z direction on the upper side and a −Z direction on the lower side), that an X-direction corresponds to a left-right direction (a +X direction on the right side and a −X direction on the left side), and that a Y-axis direction corresponds to a front-rear direction (a +Y direction on the rear side and a −Y direction on the front side). The description will be given on the basis of these definitions. The foregoing definitions are also applied to FIGS. 3 to 26. Relative ratios in size and thickness of respective layers depicted in the respective drawings such as FIG. 1 are presented for convenience of explanation. Actual size and thickness ratios are not limited to these specific ratios. The directional definitions and the size and thickness ratios described above are also applied to the figures from FIG. 2 to FIG. 27.

A light emitting device according to the present disclosure is available as a lighting device, a display device, and the like. Description of the following first to fifth embodiments will continue on an assumption that the light emitting device according to the present disclosure constitutes a display device by way of example.

### 1 First Embodiment

### [1-1 Configuration of Light Emitting Device]

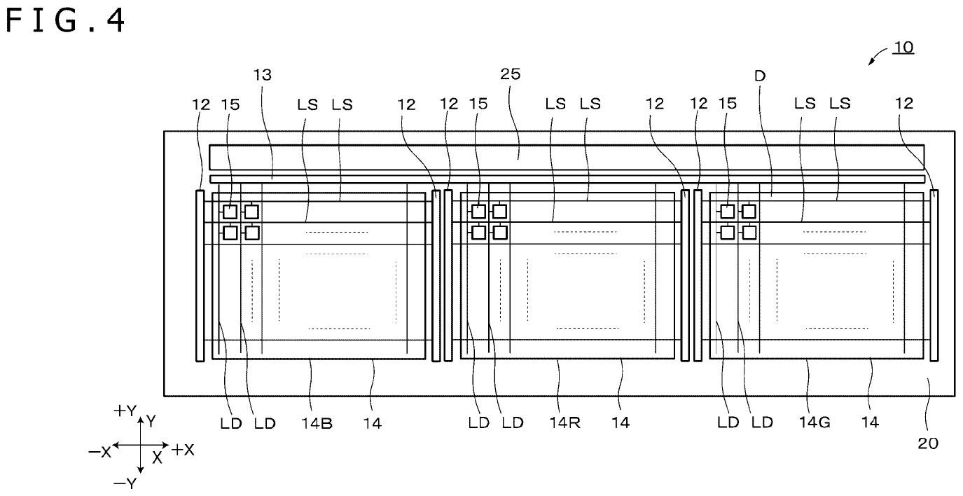

A light emitting device 10 according to the first embodiment which is one embodiment of the present disclosure constitutes a display device. As depicted in FIGS. 1, 2, 3, and 4, the light emitting device 10 includes a drive substrate 20 constituting a main substrate and multiple light emitting element arrays 30. According to the example depicted in FIGS. 1 and 2, three light emitting element arrays 30B, 30R, and 30G are provided as the light emitting element arrays 30 as described below. FIG. 1 is a plan diagram depicting the light emitting device 10 according to one example of the first embodiment. FIG. 2 is a cross-sectional diagram depicting the light emitting device 10 according to the one example. FIG. 3 is a cross-sectional diagram depicting a light emitting element provided on the light emitting element array in one example. FIG. 4 is a diagram for explaining a configuration which controls driving of light emitting elements 40 of the light emitting device 10.

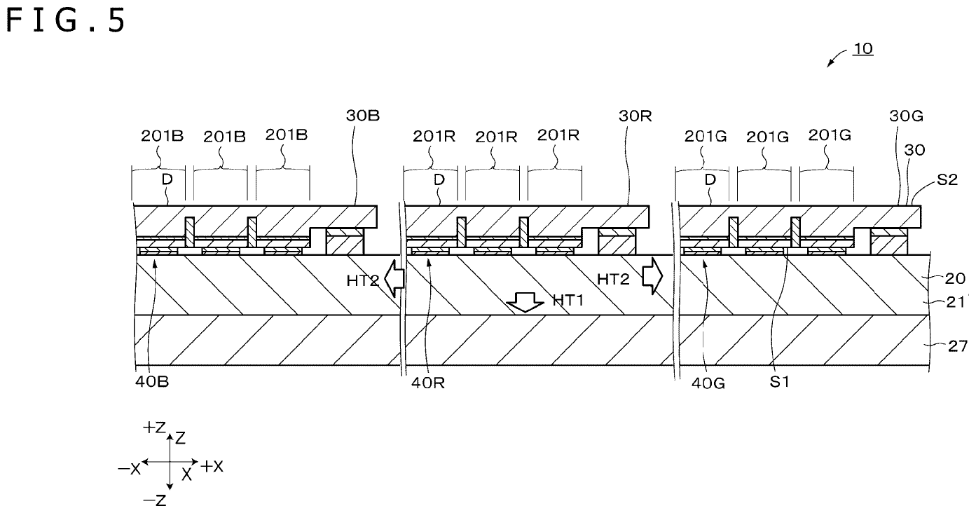

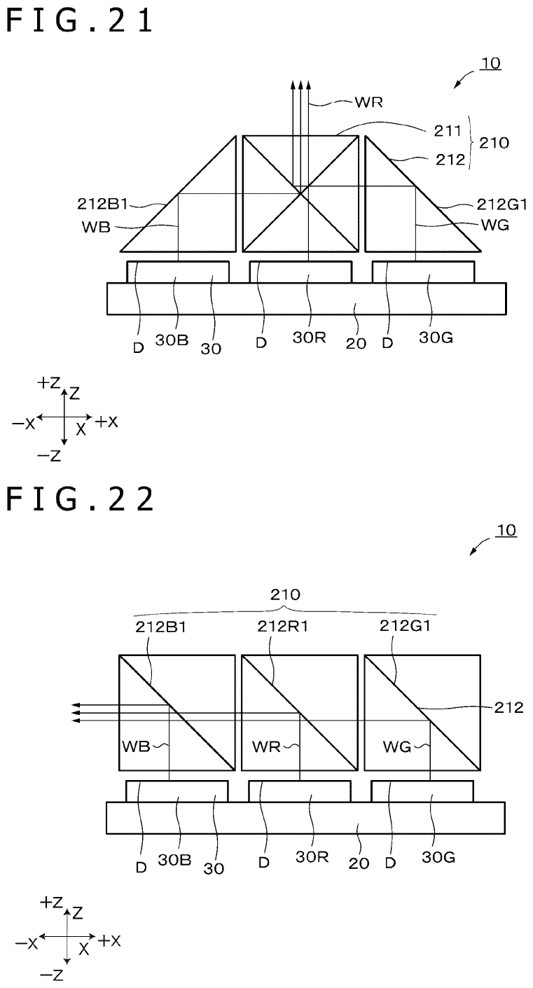

Note that, while FIGS. 1 and 2 each depict a state where the multiple light emitting elements are provided, the number of the light emitting elements 40 provided on each of the light emitting element arrays 30 is not limited to the number depicted in each of FIGS. 1 and 2. In addition, the number of the light emitting elements 40 provided on each of the light emitting element arrays 30 is not equalized between FIGS. 1 and 2 for convenience of explanation. This is also applied to FIGS. 4 to 6 and FIGS. 8 to 20. The number of the light emitting elements 40 provided on each of the light emitting element arrays 30 is not limited to the number depicted in each of FIGS. 4 to 6 and FIGS. 8 to 20. Moreover, a part of each of the multiple light emitting element arrays 30 is not depicted in FIG. 2. This is also applied to FIGS. 5, 6, 8, 10, and 13 to 20. While a connection structure between a first electrode 41 described below and the drive substrate 20 is depicted in FIG. 3, the connection structure between the first electrode 41 and the drive substrate 20 in each of the light emitting elements 40 is not limited to the connection structure depicted in FIG. 3. An auxiliary circuit 25 provided for the light emitting element arrays 30 in FIG. 1 is not positionally aligned with the auxiliary circuit 25 in FIG. 4 for convenience of explanation. Moreover, the light emitting elements 40 are not depicted in each of FIGS. 21 to 26 for convenience of explanation.

### (Light Extraction Surface)

As depicted in FIG. 1, each of light emitting element arrays 30B, 30R, and 30G included in the light emitting device 10 has a light extraction surface D through which light generated from the light emitting elements 40 is extracted. The light extraction surface D is formed on the side (non-facing surface S2 side) opposite to a facing surface S1 facing the drive substrate 20.

In the explanation of the present description, it is assumed that a surface facing the light extraction surface D of the light emitting device 10 (the surface on the side of the +Z direction) will be referred to as a first surface (upper surface), and that a surface facing the side opposite to the light extraction surface D of the light emitting device 10 (the surface on the side of the −Z direction) will be referred to as a second surface (lower surface).

### (Configuration of Sub-Pixel)

The light emitting device 10 in the example depicted in FIG. 1 has multiple pixels. One pixel included in the light emitting device 10 has a combination of multiple sub-pixels 201 corresponding to multiple color types. In this example, three colors of blue, red, and green are designated as the multiple color types, and three sub-pixels of a sub-pixel 201B, a sub-pixel 201R, and a sub-pixel 201G are provided as the sub-pixels. The sub-pixel 201B, the sub-pixel 201R, and the sub-pixel 201G are a blue sub-pixel, a red sub-pixel, and a green sub-pixel, respectively, and achieve blue display, red display, and green display, respectively. However, the example depicted in FIG. 1 is presented only by way of example, and the color types of the multiple sub-pixels are not limited to the color types of this example. Moreover, for example, a wavelength in a range from 440 to 480 nm (blue wavelength band), a wavelength in a range from 610 to 650 nm (red wavelength band), and a wavelength in a range from 510 to 590 nm (green wavelength band) can respectively be designated as main wavelengths of rays of light corresponding to the respective color types of blue, red, and green. Further, each layout of the individual sub-pixels 201B, 201R, and 201G included in the respective light emitting element arrays is not limited to any specific layout. For example, adoptable is such a layout where the individual sub-pixels 201 each having a rectangular shape are arranged in a matrix form. According to the example in FIG. 1, for example, the multiple sub-pixels 201B included in the light emitting element array 30B are two-dimensionally provided within a predetermined region of the light extraction surface D of the light emitting element array 30B. The multiple sub-pixels 201R included in the light emitting element array 30R are two-dimensionally provided within a predetermined region of the light extraction surface D of the light emitting element array 30R. The sub-pixels 201G included in the light emitting element array 30G are two-dimensionally provided within a predetermined region of the light extraction surface D of the light emitting element array 30G. However, the layout of the pixels and the sub-pixels 201 in the light emitting device 10 according to the first embodiment is not limited to this example. Any appropriate layout may be adopted as the layout of the pixels and the sub-pixels 201, such as a stripe layout and a delta layout.

The light emission state of each of the pixels is specified as a light emission state corresponding to combined rays of light emitted from the sub-pixels 201R, 201G, and 201B determined for each of the pixels.

In the explanation of the present description, each of the sub-pixels 201R, 201G, and 201B will collectively be referred to as the sub-pixel 201 in a case where no type distinction is particularly needed between the types of the sub-pixels 201R, 201G, and 201B.

### (Light Emission Control by Light Emitting Device)

As depicted in FIG. 4, the light emitting device 10 includes vertical scanning circuits (scanning line drive circuits) 12, a horizontal scanning circuit (data line drive circuit) 13, and pixel units 14 disposed on a semiconductor substrate (substrate 21) such as a silicon substrate, for example. FIG. 4 is a diagram explaining a drive control circuit of the light emitting device 10. Note that the auxiliary circuit 25 described below is located at a position different from the position of the auxiliary circuit 25 in the examples in FIGS. 1 and 2 and other examples for convenience of explanation. Each of the pixel units 14 is provided at the portion where the corresponding light emitting element array 30 is formed. In the example depicted in FIG. 4, the three pixel units 14, i.e., a pixel unit 14R, a pixel unit 14G, and a pixel unit 14B, are arranged in a line. Each of the pixel units 14 has pixel circuits 15. Each of the pixel circuits 15 includes, for each pixel, the light emitting element 40 constituting the light emitting element array 30, and a drive circuit for controlling a light emission state of the light emitting element 40. In this case, the drive circuits of the three pixel units 14 control light emission of the sub-pixels 201 corresponding to red, blue, and green (what are generally called three primary colors), respectively. In the three pixel units 14 according to the example of FIG. 4, the pixel unit 14R has the pixel circuits 15 corresponding to red in the light three primary colors, the pixel unit 14B has the pixel circuits 15 corresponding to blue, and, further, the pixel unit 14G has the pixel circuits 15 corresponding to green. A combination of the sub-pixels 201 in the display of the three pixel units 14 represents one dot of a color image. For example, a CMOS circuit is available as the drive circuit constituting each of the pixel circuits 15. Note that each of the pixel units 14 is capable of determining the pixel circuits 15 for any one of a case where two or less types of the sub-pixels 201 are present (a case where two or more types of the light emitting element arrays 30 are provided), a case where the number of types of the sub-pixels 201 exceeds three (a case where three or more types of the light emitting element arrays 30 are provided), and a case where the one light emitting element array 30 incorporates multiple types of the sub-pixels 201 (for example, the light emitting element array 30 includes the light emitting elements 40 configured to emit rays of light in two or more colors). Note that each of the pixel unit 14R, the pixel unit 14G, and the pixel unit 14B in the present description will collectively and simply be referred to as the pixel unit 14 in a case where no type distinction is particularly needed between the pixel unit 14R, the pixel unit 14G, and the pixel unit 14B.

For each of the pixel units 14, multiple scanning lines LS extend in a horizontal direction within the pixel unit 14 from the vertical scanning circuit 12, while multiple data lines LD extend in a vertical direction within the pixel unit 14 from the horizontal scanning circuit 13. According to the example in FIG. 4, the pixel circuits 15 are connected in a matrix form to the data lines LD extending in the vertical direction and the scanning lines LS extending in the horizontal direction.

As depicted in FIG. 4, the scanning line LS is wired for each pixel row in a row direction (an array direction of the pixels (sub-pixels 201) in a pixel row) for the array of the pixel circuits 15 in the matrix form in each of the three pixel units 14 (pixel units 14R, 14G, 14B). The data line LD is provided for each column of the sub-pixels 201 in a column direction (an array direction of the sub-pixels 201 in a pixel column) for the array of the pixel circuits 15 in the matrix form.

Each of the scanning lines LS is connected to an output end of the corresponding row of the vertical scanning circuit 12. Each of the data lines LD is connected to an output end of the corresponding column of the horizontal scanning circuit 13.

The horizontal scanning circuit 13 supplies data signals to each of the data lines LD. Each of the vertical scanning circuits 12 includes a shift register circuit or the like. Each of the vertical scanning circuits 12 sequentially scans (achieves linear sequential scanning of) the pixel circuits 15 of the pixel unit 14 for each row by sequentially supplying write scanning signals to each of the scanning lines LS. Moreover, each of the vertical scanning circuits 12 controls light emission and non-emission (quenching) of the pixel circuits 15 by supplying control signals to the pixel circuits 15. In such a manner, control of the pixel units 14 is achieved for each of the pixel circuits 15. Accordingly, driving states of the light emitting element arrays 30 are controlled for each of the light emitting elements 40. Note that, while the horizontal scanning circuit 13 in FIG. 4 is provided as a common circuit for the light emitting element arrays 30 corresponding to the pixel units 14R, 14G, and 14B, this configuration is presented only by way of example. For example, the light emitting device 10 may have the dedicated horizontal scanning circuit 13 for each of the light emitting element arrays 30 provided for the corresponding pixel units 14R, 14G, and 14B.

### (Drive Substrate)

As depicted in FIG. 2, the drive substrate 20 includes the substrate 21. The drive substrate 20 has a structure which includes various circuits provided on the substrate 21 to drive the multiple light emitting elements 40. For example, the various circuits can include a drive circuit for controlling driving of the light emitting elements 40 as described above, and a power source circuit for supplying power to the multiple light emitting elements 40 (both the circuits are not depicted). As described above, a CMOS circuit is available as the drive circuit for controlling driving of the light emitting elements 40, for example.

Pads (not depicted) which constitute terminals electrically connected to the first electrode 41, a second electrode 42, and the like of each of the light emitting elements 40 are formed on the first surface of the drive substrate 20. Each of the pads includes a conductive material, and is connected to a contact wiring portion (not depicted) provided on the substrate 21. The contact wiring portion is connected to the various circuits provided on the substrate 21, such as the drive circuits. According to the example in FIG. 2, the pad electrically connected to the second electrode 42 may be formed at each of positions corresponding to the individual light emitting elements 40. Moreover, the pad connected to each of the first electrodes 41 may be formed in correspondence with the layout of the first electrodes 41. For example, the pad connected to each of the first electrodes 41 may also be formed at a position corresponding to a circumferential edge of each of the light emitting element arrays 30. Note that this configuration is presented only by way of example. The positions and the number of the pads connected to the first electrodes 41 may be determined according to the layout of the light emitting elements 40 of the light emitting element arrays 30.

### (Substrate)

For example, the substrate 21 may include glass or resin having low transmissibility of moisture and oxygen, or may include a semiconductor where transistors and the like are easily formed. Specifically, the substrate 21 may be a glass substrate, a semiconductor substrate, a resin substrate, or the like. For example, the glass substrate includes high strain point glass, soda glass, borosilicate glass, forsterite, lead glass, quartz glass, or the like. For example, the semiconductor substrate includes amorphous silicon, polycrystalline silicon, monocrystal silicon, or the like. For example, the resin substrate includes at least one type of a material selected from a group including polymethyl methacrylate, polyvinyl alcohol, polyvinyl phenol, polyether sulfone, polyimide, polycarbonate, polyethylene terephthalate, polyethylene naphthalate, and the like.

### (Light Emitting Element Array)

The light emitting device 10 has the multiple light emitting element arrays 30 on the first surface side of the one drive substrate 20. In other words, the multiple light emitting element arrays 30 are provided on the same drive substrate 20. Each of the light emitting element arrays 30 has a structure including a light emitting element group where the multiple light emitting elements 40 each independently driven are arranged. The light emitting element group in each of the light emitting element arrays 30 is preferably constituted by the three or more light emitting elements 40, more preferably by the ten or more light emitting elements 40, and further preferably by the 100 or more light emitting elements 40. The light emitting element group may be constituted by 1,000 or more light emitting elements 40.

### (Shape of Light Emitting Element Array)

Each of the light emitting element arrays 30 included in the light emitting device 10 depicted in the example of FIG. 2 is formed as a sub substrate which is different from (a separate body of) the drive substrate 20 constituting a main substrate. In addition, each of the light emitting element arrays 30 is a panel having a structure where the multiple light emitting elements 40 are integrated with each other via a first compound semiconductor layer 44 described below. However, this configuration is presented only by way of example. For example, as described below with reference to FIG. 5 and other figures, the multiple light emitting elements 40 in each of the light emitting element arrays 30 may be integrated with each other by a protection layer 51 covering a side portion of each of the light emitting elements 40 as a layer that separates the adjoining light emitting elements 40 from each other and that is interposed between the side portions of the respective light emitting elements 40.

### (Number of Colors of Light Emitting Element Arrays)

The number of colors of the light emitting element arrays 30 is not limited to a specific number. According to the example depicted in FIGS. 1 and 2 and other figures, the three types of the light emitting element arrays 30R, 30G, and 30B having different light emission colors are provided on the drive substrate 20. The light emitting element array 30R emits red light WR from the light extraction surface D. The light emitting element array 30G emits green light WG from the light extraction surface D. The light emitting element array 30B emits blue light WB from the light extraction surface D.

The light emitting element array 30R has light emitting elements 40R each having a red emission color. The light emitting element array 30G has light emitting elements 40G each having a green emission color. The light emitting element array 30B has light emitting elements 40B each having a blue emission color. Note that the emission colors of the light emitting elements 40 are not limited to the emission colors depicted in the example of FIGS. 1 and 2 and other figures and presented only by way of example.

In addition, each of the light emitting element arrays 30R, 30G, and 30B in the present description is collectively and simply referred to as the light emitting element array 30 in a case where no type distinction is particularly needed between the light emitting element arrays 30R, 30G, and 30B.

According to the example depicted in FIGS. 1 and 2 and other figures, the light emitting elements 40 provided on the multiple light emitting element arrays 30 designate different color types as the emission colors. This configuration does not exclude such a configuration where the multiple light emitting elements 40 provided on at least the two light emitting element arrays 30 designate the same color type as the emission colors. Accordingly, the light emitting elements 40 provided on at least the two light emitting element arrays 30 may be either light emitting elements for emitting rays of light each having a main wavelength approximately in the same wavelength band, or light emitting elements for emitting rays of light each having a main wavelength in a completely different wavelength band.

Each of the emission colors of the light emitting elements 40 provided on the light emitting element arrays 30 may be determined according to the color type of the sub-pixels 201. Specifically, the light emitting elements 40 may be configured such that red light, green light, and blue light are emitted from respective light emission surfaces of the corresponding sub-pixels 201R, 201G, and 201B, respectively, in correspondence with each other.

The layout of the light emitting elements 40 is not particularly limited to any layout. According to the example depicted in FIG. 1, the layout of the light emitting elements 40 is determined according to the layout of the sub-pixels 201. Specifically, for each of the light emitting element arrays 30, the multiple light emitting elements 40 are two-dimensionally arranged in such an arrangement pattern as a matrix form, according to the matrix-shaped layout of the sub-pixels 201. According to the example of FIG. 1, the sub-pixels 201 and the light emitting elements 40 are arranged in the X-axis direction and the Y-axis direction in a planar view of the light emitting element arrays 30.

### (Light Emitting Element)

As depicted in the example in FIGS. 1 and 2, each of the light emitting elements 40 constituting at least the one light emitting element array 30 included in the light emitting device 10 according to the first embodiment is a compound semiconductor light emitting element (Light Emitting Diode) (LED element). However, this configuration does not exclude such a configuration where each of the light emitting elements 40 constituting the light emitting element arrays 30 included in the light emitting device 10 according to the present disclosure is a component other than an LED element. The type of the light emitting elements 40 is not particularly limited to any type. For example, as described in the second and third embodiments described below, each of the light emitting elements 40 may be an organic EL light emitting element (Organic Light Emitting Diode) (hereinafter also referred to as an OLED element), or a light emitting element including a quantum dot. Moreover, the size of the light emitting elements 40 of the light emitting element arrays 30 in a planar view is not particularly limited to any size. For example, what is generally called a micro-OLED element or what is generally called a micro-LED element, which are more miniaturized types in OLED elements and LED elements, may be adopted as each of the light emitting elements 40. It is assumed that the micro-OLED element and the micro-LED element are an OLED element and an LED element, respectively, each having an extremely small size, such as a micrometer size and smaller than this size. The example depicted in FIGS. 1 and 2 and other figures is a case where the light emitting elements 40 constituting all of the light emitting element array 30 provided on the drive substrate 20 are LED elements.

### (Structure of LED Element)

In each of the light emitting element arrays 30, LED elements 50 constituting the light emitting elements 40 are provided for the sub-pixels 201 with one-to-one correspondence. According to the light emitting device 10 of the first embodiment, the multiple LED elements 50 are provided for each of the multiple light emitting element arrays 30. According to the example depicted in FIGS. 1 and 2, LED elements 50R emitting red light are provided on the light emitting element array 30R, LED elements 50G emitting green light are provided on the light emitting element array 30G, and LED elements 50B emitting blue light are provided on the light emitting element array 30B. Note that each of the LED elements 50R, 50G, and 50B in the present description will collectively and simply be referred to as the LED element 50 in a case where no type distinction is particularly needed between the LED elements 50R, 50G, and 50B.

According to the example depicted in FIGS. 2 and 3, each of the LED elements 50 includes a compound semiconductor laminated structure body (hereinafter referred to as a laminated structure body 43), the first electrode 41, and the second electrode 42. FIG. 3 is a cross-sectional diagram schematically depicting the one LED element 50 in one example. According to this example, the LED element 50 is formed such that both the first electrode 41 and the second electrode 42 face the first surface side of the drive substrate 20. The LED element 50 may be what is generally called a flip-chip assembly type element (FC type element). The first electrode 41 and the second electrode 42 are not depicted in FIG. 2 for convenience of explanation. A thick arrow in FIG. 3 indicates a direction of emission light WE from the LED element 50.

### (Laminated Structure Body)

The laminated structure body 43 includes multiple compound semiconductor layers laminated on each other. Specifically, the laminated structure body 43 includes a first compound semiconductor layer 44, a second compound semiconductor layer 45, and a light emitting layer 46. The laminated structure body 43 has a structure in which the light emitting layer 46 constitutes a core layer and the first compound semiconductor layer 44 and the second compound semiconductor layer 45 constitute clad layers with the core layer sandwiched therebetween. According to the example depicted in FIG. 3, the first compound semiconductor layer 44 constitutes a clad layer located near a light emitting surface (first surface) of the LED element 50, while the second compound semiconductor layer 45 constitutes a clad layer located away from the light emitting surface. The light emitting layer 46 is provided between the first compound semiconductor layer 44 and the second compound semiconductor layer 45. Note that the laminated structure body 43 is not required to have the configuration described above, and may have a laminated structure other than this configuration.

The first compound semiconductor layer 44 has a first conductivity type, while the second compound semiconductor layer 45 has a second conductivity type which is a conductivity type opposite to the first conductivity type. Specifically, for example, the first compound semiconductor layer 44 has an n-type, while the second compound semiconductor layer 45 has a p-type. In a case where the first compound semiconductor layer 44 and the second compound semiconductor layer 45 have the n-type and the p-type, respectively, currents I flow as indicated by arrows in FIG. 2, in response to conduction between the first electrode 41 and the second electrode 42. As a result, the light emitting layer 46 emits light.

The first compound semiconductor layer 44 and the second compound semiconductor layer 45 each include a compound semiconductor. For example, the compound semiconductor is a GaN-based compound semiconductor (including AlGaN mixed crystal, AlInGaN mixed crystal, or InGaN mixed crystal), an InN-based compound semiconductor, an InP-based compound semiconductor, an AlN-based compound semiconductor, a GaAs-based compound semiconductor, an AlGaAs-based compound semiconductor, an AlGaInP-based compound semiconductor, an AlGaInAs-based compound semiconductor, an AlAs-based compound semiconductor, a GaInAs-based compound semiconductor, a GaInAsP-based compound semiconductor, a GaP-based compound semiconductor, or a GaInP-based compound semiconductor.

In these compounds, n-type GaN or n-type AlGaInP (referred to as n-GaN and n-AlGaInP, respectively, in some cases) is preferably adopted as the first compound semiconductor layer 44. In addition, it is not excluded that the first compound semiconductor layer 44 has the p-type, and that the second compound semiconductor layer has the n-type. In this case, p-type AlGaInP (referred to as p-AlGaInP in some cases) is preferably adopted as the first compound semiconductor layer 44. Specifically, therefore, the first compound semiconductor layer 44 may be a compound semiconductor layer including at least one type of a material selected from a group including n-GaN, n-AlGaInP, and p-AlGaInP.

In a case where the first compound semiconductor layer 44 and the second compound semiconductor layer 45 have the n-type and the p-type, respectively, n-type impurities added to the first compound semiconductor layer 44 are such impurities as silicon (Si), selenium (Se), germanium (Ge), tin (Sn), carbon (C), or titanium (Ti). P-type impurities added to the second compound semiconductor layer 45 are such impurities as zinc (Zn), magnesium (Mg), beryllium (Be), cadmium (Cd), calcium (Ca), barium (Ba), or oxygen (O).

The first compound semiconductor layer 44 and the second compound semiconductor layer 45 may each contain a material constituting a substrate used for forming semiconductor crystal elements. Examples of the material constituting the substrate used for forming semiconductor crystal elements include sapphire, GaN, GaAs, InP, and the like.

The light emitting layer 46 includes a compound semiconductor. For example, this compound semiconductor can include a material similar to the material of the first compound semiconductor layer 44 and the second compound semiconductor layer 45. The light emitting layer 46 may be constituted by a single compound semiconductor layer, or may have a single quantum well structure (SQW structure) or a multiple quantum well structure (MQW structure).

In the laminated structure body 43, the light emitting layer 46 and the second compound semiconductor layer 45 are each a layer formed in a separated state for each of the LED elements 50, while the first compound semiconductor layer 44 is a common layer for the multiple LED elements 50 (a common layer for the multiple light emitting elements 40).

A red light emitting layer 46R emitting red light, a blue light emitting layer 46B emitting blue light, and a green light emitting layer 46G emitting green light can be formed according to a material or the like of the light emitting layer 46. Accordingly, each of the LED elements 50 can constitute any one of the LED element 50R emitting red light, the LED element 50G emitting green light, and the LED element 50B emitting blue light, according to the material or the like of the light emitting layer 46. For example, an element including a nitride-based III-V compound semiconductor can be adopted as each of the LED element 50R, the LED element 50G, and the LED element 50B.

Each of the LED elements 50 may be an ultraviolet light emitting element (including a nitride-based III-V compound semiconductor) or an infrared light emitting element (including an AlGaAs or GaAs-based compound semiconductor) included in a non-visible range and applied to a motion sensor or the like.

### (First Electrode)

The first compound semiconductor layer 44 includes the first electrode 41 disposed on the second surface side. In the state of each of the light emitting element arrays 30, the first electrode 41 is formed at a position of an outer edge of the light emitting element array 30 in a planar direction of the light emitting element array 30. The first electrode 41 is capable of functioning as a common electrode for the multiple LED elements 50. In a case where each of the light emitting element arrays 30 is mounted at a predetermined position on the drive substrate 20, the first electrode 41 is electrically connected to a pad formed on the drive substrate 20. The pad connected to the first electrode 41 is capable of functioning as an auxiliary electrode for the first electrode 41.

### (Material of First Electrode)

For example, the first electrode 41 can include a material containing at least one type of metal (including an alloy) selected from a group including gold (Au), silver (Ag), palladium (Pd), platinum (Pt), nickel (Ni), Al (aluminum), Ti (titanium), tungsten (W), vanadium (V), chromium (Cr), copper (Cu), Zn (zinc), tin (Sn), and indium (In).

For example, the first electrode 41 has a single layer configuration or a multiple layer configuration. Examples of the multiple layer configuration include Ti/Au, Ti/Al, Ti/Pt/Au, Ti/Al/Au, Ni/Au, AuGe/Ni/Au, Ni/Au/Pt, Ni/Pt, Pd/Pt, Ag/Pd, or the like. In a case where the first electrode 41 has the multiple layer configuration, the layer before “/” and located closer to the head in each of the multiple layer configurations is disposed at a position closer to an active layer. This is also applied to a case where the second electrode 42 has the multiple layer configuration.

Moreover, in addition to the materials described above, examples of the material of the first electrode 41 include indium oxide, indium-tin oxide (ITO, including Sn-doped In₂O₃, crystalline ITO, and amorphous ITO), indium-zinc oxide (IZO), indium-gallium oxide (IGO), indium-doped gallium-zinc oxide (IGZO, In—GaZnO₄), IFO (F-doped In₂O₃), tin oxide (SnO₂), ATO (Sb-doped SnO2), FTO (F-doped SnO₂), zinc oxide (ZnO, including Al-doped ZnO, B-doped ZnO, Ga-doped ZnO), antimony oxide, spinel oxide, and oxide having a YbFe₂O₄ structure.

### (Second Electrode)

The second electrode 42 is individually and electrically connected to the second compound semiconductor layer 45 of the corresponding laminated structure body 43. According to the example of FIG. 1, the second electrode 42 is provided immediately below (on the second main surface side of) the second compound semiconductor layer 45.

Similarly to the first electrode 41 described above, examples of the material of the second electrode 42 include indium oxide, indium-tin oxide (ITO, including Sn-doped In₂O₃, crystalline ITO, and amorphous ITO), indium-zinc oxide (IZO), indium-gallium oxide (IGO), indium-doped gallium-zinc oxide (IGZO, In—GaZnO₄), IFO (F-doped In₂O₃), tin oxide (SnO₂), ATO (Sb-doped SnO2), FTO (F-doped SnO₂), zinc oxide (ZnO, including Al-doped ZnO, B-doped ZnO, Ga-doped ZnO), antimony oxide, a spinel oxide, and an oxide having a YbFe₂O₄ structure.

Moreover, for example, the second electrode 42 can include a material containing at least one type of metal (including an alloy) selected from a group including gold (Au), silver (Ag), palladium (Pd), platinum (Pt), nickel (Ni), Al (aluminum), Ti (titanium), tungsten (W), vanadium (V), chromium (Cr), copper (Cu), zinc (Zn), tin (Sn), and indium (In).

### (Metal Layer)

Each of the light emitting element arrays 30 is joined onto the first surface of the drive substrate 20 to be mounted on the light emitting device 10. According to the example in FIG. 3, the LED element 50 is mounted by flip-chip assembly. In this case, the first electrode 41 of the light emitting element array 30 is electrically connected to a pad on the drive substrate 20. Moreover, the second electrode 42 is electrically connected to a pad on the drive substrate 20. The pad connected to the second electrode 42 is electrically connected to a drive circuit, such as a CMOS, formed on the drive substrate 20. The method for electric connection between the first electrode 41 and the pad is not limited to any specific method. For example, a connecting method via the metal layer 52 can be adopted. The method for electric connection between the second electrode 42 and the pad may be a method similar to the method for electric connection between the first electrode 41 and the pad. According to the example of FIG. 3, the first electrode 41 and the second electrode 42 of the LED element 50 are respectively connected, via the metal layer 52, to the pads formed on the first surface of the drive substrate 20.

For example, the metal layer 52 can be a bump or the like. For example, the metal layer 52 can include solder, nickel, gold, silver, copper, tin, or the like, or an alloy of these materials.

### (Protection Layer)

In each of the light emitting element arrays 30 in the example depicted in FIG. 2, the second compound semiconductor layers 45 and the light emitting layers 46 constituting the adjoining LED elements 50 are divided by the protection layer 51. The protection layer 51 can function as a dividing layer for dividing the second compound semiconductor layer 45 and the light emitting layer 46 for each of the individual LED elements 50. The protection layer 51 provided between the adjoining LED elements 50 protects side surfaces of the second compound semiconductor layer 45 and the light emitting layer 46 of each of the LED elements 50.

Moreover, the protection layer 51 partially divides the first compound semiconductor layer 44 at positions of the adjoining LED elements 50.

It is preferable that the protection layer 51 contain at least one type of a material selected from a group including a dielectric, resin, and metal. For example, the protection layer 51 can include a material of one or more types selected from a group including SiOₓ-based material, SiN_{Y}-based material, and SiO_{X}N_{Y}-based material, or a material containing Ta₂O₅, ZrO₂, AlN, or Al₂O₃. The protection layer 51 preferably includes an insulating material.

### (Auxiliary Circuit)

The drive substrate 20 may include the auxiliary circuit 25 in addition to the pixel unit 14 having the circuit (e.g., CMOS) for driving the light emitting elements 40 of the light emitting element arrays 30, the vertical scanning circuit 12, and the horizontal scanning circuit 13 described above. For example, the auxiliary circuit 25 can include display driver ICs (Display Driver Integrated Circuits: DDIC), a timing control circuit, a memory, a sensor, image processing ICs (Integrated Circuits), and the like. The auxiliary circuit 25 may be provided inside the drive substrate 20, or may be provided on an IC chip formed separately from the drive substrate 20. In a case where the auxiliary circuit 25 is provided on an IC chip, this IC chip corresponds to a sub-substrate different from the main substrate (separated from the main substrate) such as the drive substrate 20, similarly to the light emitting element arrays 30. However, the IC chip has such a structure where electronic components and integrated circuits corresponding to functions and the like are mounted on a substrate (not particularly depicted), and therefore is different from the light emitting element arrays 30.

### (FPC)

As depicted in the example of FIG. 1, a flexible print circuit board (Flexible Printed Circuits; FPC) (FPC 26 in FIG. 1) may be connected to the drive substrate 20 to which the light emitting element arrays 30 are connected. The FPC 26 electrically connects the drive substrate 20 with external devices and circuits. The FPC 26 is connected to the drive substrate 20 via a first terminal 26A on one of ends of the FPC 26, and connected to an external device (not depicted) or the like via a second terminal 26B on the other end of the FPC 26.

### [1-2 Manufacturing Method of Light Emitting Device]

For example, the light emitting device 10 according to the first embodiment can be manufactured by the following manufacturing method. Note that a manufacturing method of the light emitting device 10 depicted in FIG. 1 will be described as an example of this manufacturing method. Note that described will be a manufacturing method in a case where the light emitting device 10 is produced using a chip-on-wafer process.

### (Formation of Light Emitting Element Array)

An element substrate (not depicted) is prepared. A material of the element substrate can be sapphire, silicon, or the like. The laminated structure body 43 is formed on a surface of the element substrate. A method for forming the laminated structure body 43 is not limited to a specific method. For example, methods such as MOCVD (metal organic chemical vapor deposition) can be adopted.

Subsequently, the first electrode 41 and the second electrode 42 are formed at predetermined positions of the laminated structure body 43. For example, the first electrode 41 and the second electrode 42 can be formed by photolithography or other methods. In this manner, the element substrate including the light emitting element arrays 30 is formed. The element substrate may be used in a wafer state. In this case, a large number of the light emitting element arrays 30 are formed on the element substrate. The element substrate including a large number of the light emitting element arrays 30 is divided (cut) into units of the single light emitting element array 30. As a result, element substrates each including one light emitting element array are obtained (singulated) in a chip state.

The element substrates each including the light emitting element array 30 may be produced according to the types of the sub-pixels 201. According to the example of FIG. 1, three types of arrays, i.e., the light emitting element array 30B which has the light emitting element 40B having a blue emission color, the light emitting element array 30R which has the light emitting element 40R having a red emission color, and the light emitting element array 30G which has the light emitting element 40G having a green emission color, are formed. As described above, the element substrates including the respective types of the light emitting element arrays 30 described above are obtained in a singulated state.

### (Formation of Drive Substrate)

Circuits, wires, electrodes, and the like are formed at predetermined positions on the substrate 21 such as a silicon substrate. The circuits presented herein are various types of circuits provided on the drive substrate 20, such as a CMOS circuit or other drive circuits and a power source circuit. The circuits, the wires, the electrodes, and the like can be formed using etching, photolithography, or other methods. Moreover, pads are formed on a frontmost surface of the substrate 21 on which the various circuits are formed. In this manner, the drive substrate 20 is produced. The drive substrate 20 may be used either in a singulated chip-shaped state corresponding to the one light emitting device 10, or in a wafer state prior to singulation. The present explanation continues on an assumption that a subsequent step will be performed in a wafer state where the drive substrate 20 corresponding to multiple light emitting devices 10 is formed.

### (Junction Between Light Emitting Element Array and Drive Substrate)

The element substrates each including the light emitting element array 30 are arranged at predetermined positions on the drive substrate 20. At this time, the first electrode 41 and the second electrode 42 of the light emitting element array 30 are arranged at positions facing pads on the drive substrate 20 via the metal layer 52. The element substrates each including the light emitting element array 30 are electrically connected to the predetermined positions on the drive substrate 20 via the metal layer 52. Thereafter, the element substrates are removed as necessary. The arrangement of the light emitting element arrays 30 onto the drive substrate 20 is carried out according to a layout of the sub-pixels 201. For example, in a case where the three types of sub-pixels 201B, 201R, 201G are disposed in a single line form, the light emitting element arrays 30B, 30R, and 30G are arranged at predetermined positions on the drive substrate in a single line form.

The auxiliary circuit 25 may be assembled during formation of the drive substrate 20. Moreover, even in a case where the auxiliary circuit is not assembled, an IC chip including circuits corresponding to the auxiliary circuit 25 may be connected to the drive substrate 20 as necessary.

The drive substrate 20 in the wafer state is singulated into pieces each corresponding to the single light emitting device 10. Moreover, the FPC 26 is connected to a predetermined position of the drive substrate 20 as necessary. In this manner, the light emitting device 10 is produced.

### [1-3 Operation and Advantageous Effects]

A conventional light emitting device is manufactured by forming multiple drive substrates each including one light emitting element array, arranging the multiple drive substrates, and then providing a circuit board for controlling operations of the respective drive substrates. Accordingly, it is required for this type of conventional light emitting device to leave a sufficient space for arrangement of the multiple drive substrates in a case where the multiple light emitting element arrays are arranged in a predetermined layout. Moreover, in a case where the light emitting device has multiple types of light emitting element arrays, it is required to carry out a step of forming a drive substrate including a light emitting element array for each of light emitting element arrays during manufacture of the light emitting device. For example, in a case where the light emitting device has three types of arrays, i.e., a light emitting element array which has a light emitting element having a red emission color, a light emitting element array which has a light emitting element having a blue emission color, and a light emitting element array which has a light emitting element having a green emission color, it is required to carry out a step of manufacturing a drive substrate including a light emitting element array for each of the color types.

According to the light emitting device 10 of the first embodiment, the multiple light emitting element arrays 30 are provided on the one drive substrate 20 as depicted in FIGS. 1 and 2. Accordingly, the light emitting device 10 of the first embodiment is capable of improving space efficiency in securing a space for the light emitting element arrays 30.

According to the light emitting device 10 of the first embodiment, the multiple light emitting element arrays 30 are provided on the one drive substrate 20 as depicted in FIG. 3. Accordingly, reduction of the steps for manufacturing the drive substrates including the light emitting element arrays (reduction of the number of manufacturing steps), and therefore, reduction of manufacturing costs are achievable.

Some of conventional light emitting devices include a heat dissipation structure, such as a heat sink, immediately below each of drive substrates (on the side where the light emitting element arrays are not formed). In this case, heat or the like generated by light emission of the light emitting element arrays is dissipated by the heat dissipation structure immediately below the drive substrates including these light emitting element arrays.

According to the light emitting device 10 of the first embodiment, the multiple light emitting element arrays 30 are provided on the one drive substrate 20. Accordingly, a heat dissipation structure 27 can be provided on the second surface side of the one drive substrate 20 as depicted in FIG. 5. FIG. 5 is a cross-sectional diagram for explaining a state where the heat dissipation structure 27 is provided on the light emitting device 10. The heat dissipation structure 27 having a heat dissipation surface wider than that of the conventional light emitting device can be provided on the light emitting device 10. According to the light emitting device 10, a portion of the heat dissipation structure 27 immediately below the drive substrate including the light emitting element arrays 30 and a portion of the heat dissipation structure 27 at a position outside the forgoing portion of the heat dissipation structure 27 are available as portions for heat dissipation of heat generated by light emission of the light emitting element arrays 30 or the like. For example, in a specific case where only the light emitting element array 30R emits light with no emission from the light emitting element array 30B and the light emitting element array 30G, heat generated by the light emitting elements 40R of the light emitting element array 30R is dissipated not only in a direction of an arrow HT1 from the portion of the heat dissipation structure 27 immediately below the light emitting element array 30R, but also from the portions of the heat dissipation structure 27 immediately below the light emitting element array 30B and the light emitting element array 30G. Accordingly, heat dissipation is achievable in directions of arrows HT2 in FIG. 5. As apparent from above, the light emitting device 10 according to the first embodiment is also capable of improving heat dissipation performance.

According to the light emitting device 10 of the first embodiment, the multiple light emitting element arrays 30 are provided on the one drive substrate 20. Accordingly, wires connecting the multiple light emitting element arrays 30 can be provided within the drive substrate 20.

Moreover, as will be described below, the light emitting device 10 in a certain case includes an optical system 210 which integrates rays of light generated from the light emitting element arrays 30 on the light extraction surface D side of the light emitting element arrays 30. In this case, the optical system 210 and the light emitting element arrays 30 are easily positioned in the configuration where the multiple light emitting element arrays 30 are provided on the one drive substrate 20.

Described next will be modifications of the light emitting device 10 according to the first embodiment.

### 1-4 Modifications

### Modification 1

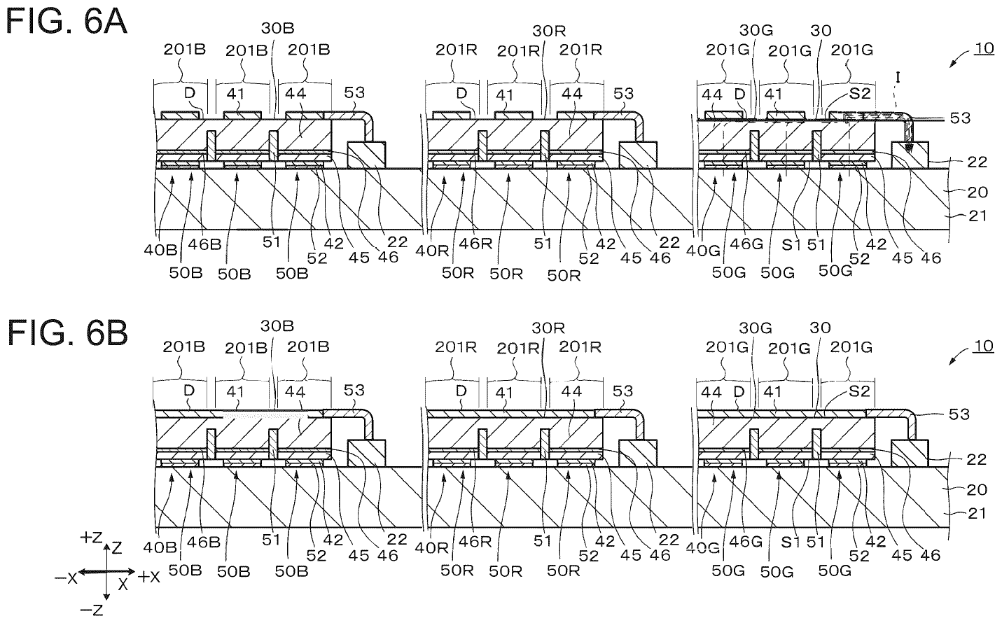

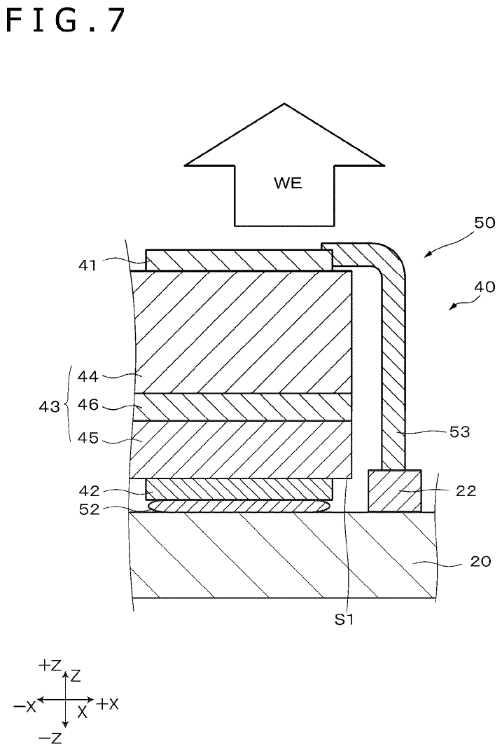

According to the light emitting device 10 of the first embodiment, each of the LED elements 50 constituting the light emitting elements 40 may be configured such that the first electrode 41 and the second electrode 42 are formed on the first surface side and the second surface side of the laminated structure body 43, respectively, as depicted in FIG. 6A and FIG. 7. This mode will be referred to as modification 1 of the first embodiment. FIG. 6A is a cross-sectional diagram for explaining the light emitting device 10 according to one example of modification 1. FIG. 7 is a cross-sectional diagram for explaining the LED element 50 constituting the light emitting element 40 according to one example. In this case, the first electrode 41 may be electrically connected to a pad (pad 22) of the drive substrate 20 by use of a wire 53 or the like. The second electrode 42 may be electrically connected to a pad (not depicted) of the drive substrate 20 via the metal layer 52 or the like as described in detail in the first embodiment. Conductive metal such as aluminum, silver, and gold can be used as the wire 53. Note that FIG. 6A depicts the wire 53 connecting a part of the first electrodes 41 to the pad 22 for convenience of explanation.

In FIG. 6A, each of the first electrodes 41 is separately provided for the corresponding one of the LED elements 50. However, this configuration is presented only by way of example. As depicted in FIG. 6B, the first electrode 41 may be a common layer for the multiple LED elements 50. FIG. 6B is a cross-sectional diagram schematically depicting the light emitting device 10 according to one example of the modification of the first embodiment.

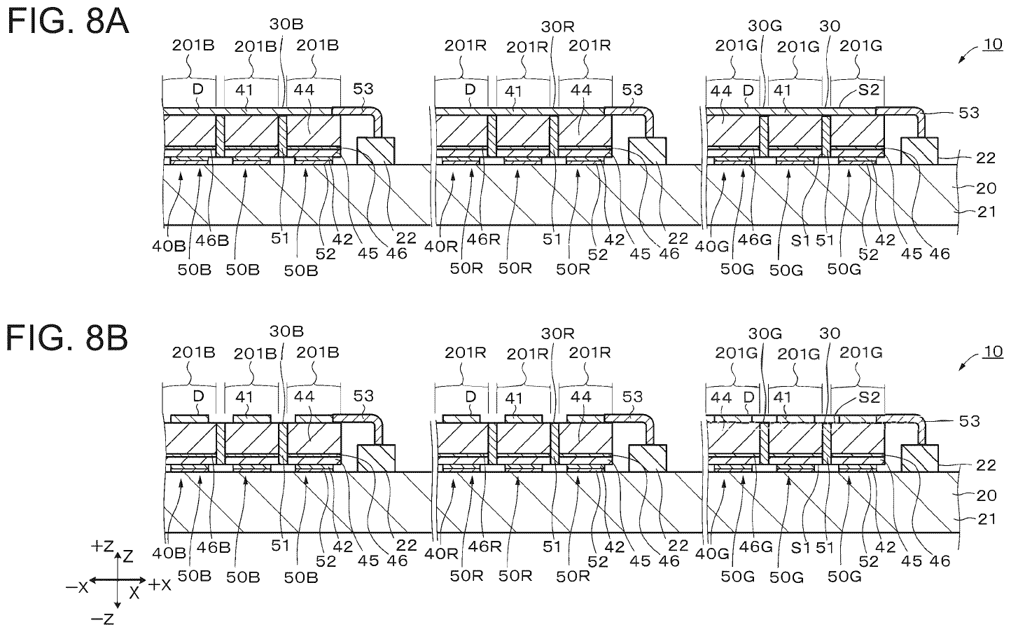

In FIG. 6A and FIG. 6B, the first compound semiconductor layer 44 is a common layer for the multiple LED elements 50. Meanwhile, the second compound semiconductor layer 45 and the light emitting layer 46 are each a layer separately provided for the corresponding one of the LED elements 50. However, this configuration is presented only by way of example. As depicted in FIG. 8A and FIG. 8B, the first compound semiconductor layer 44 may be a layer separated for each of the LED elements 50. According to examples of FIG. 8A and FIG. 8B, the protection layer 51 is formed between the adjoining LED elements 50. Even in this case, the first electrode 41 may be either a layer separated for each of the LED elements 50 (FIG. 8B), or a common layer for the multiple LED elements 50 (FIG. 8A).

Note that, while described with reference to FIGS. 2, 6, and 8 presenting the first embodiment and modification 1 of the first embodiment described above have been the examples of the case where the multiple light emitting element arrays 30 have the common structure, the multiple light emitting element arrays 30 may have different structures. For example, the light emitting element array 30B may have the structure depicted in FIG. 2, the light emitting element array 30R may have the structure depicted in FIG. 6A, and the light emitting element array 30G may have the structure depicted in FIG. 8B.

### Modification 2

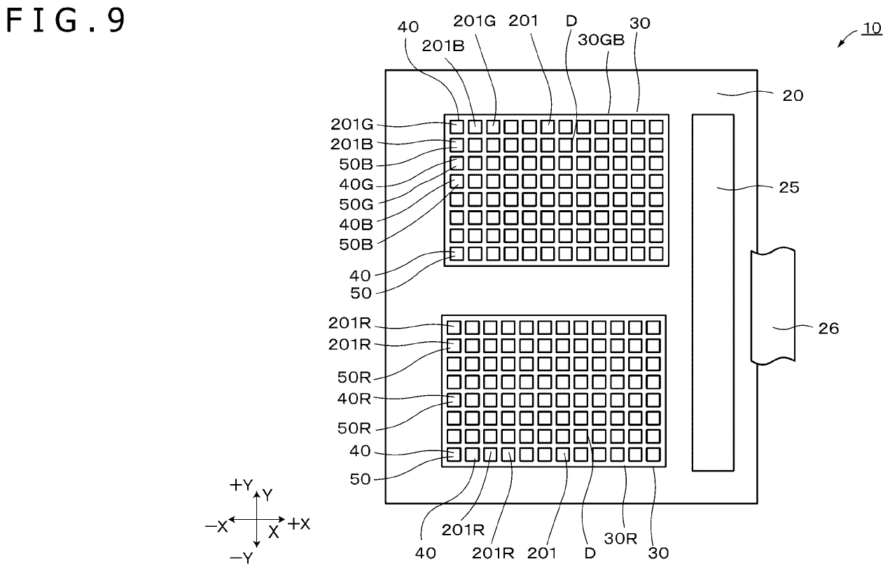

The light emitting device 10 according to the first embodiment is not limited to the light emitting device configured such that each of the light emitting element arrays 30 described above has the light emitting elements 40 corresponding to one type of the sub-pixels 201. According to the light emitting device 10 of the first embodiment, at least one of the light emitting element arrays 30 may include light emitting elements corresponding to multiple sub-pixels as depicted in FIG. 9. This mode will be referred to as modification 2 of the first embodiment. FIG. 9 is a plan diagram for explaining the light emitting device 10 according to one example of modification 2 of the first embodiment.

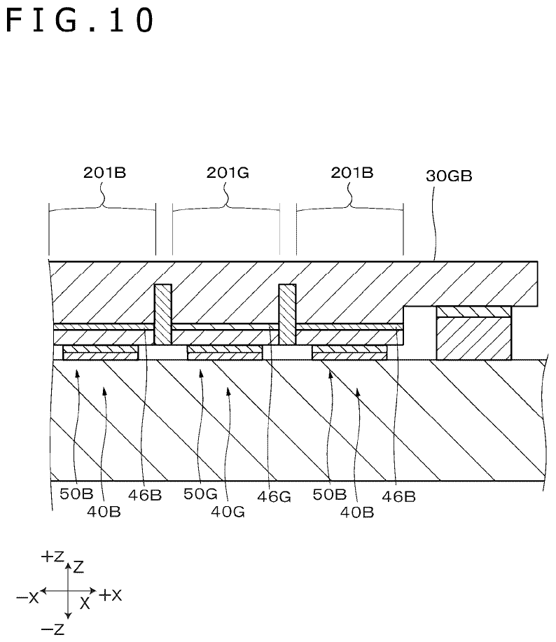

According to the example of FIG. 9, a first light emitting element array that emits light in a first color and a second light emitting element array that emits rays of light in multiple colors different from the first color are provided as light emitting element arrays. Specifically, the light emitting device 10 includes the light emitting element array 30R and a light emitting element array 30GB. The light emitting element array 30R includes the light emitting element 40R emitting red light as the first color light, and has a single emission color. The light emitting element array 30GB includes the light emitting element 40G having a green emission color different from the first color and the light emitting element 40B having a blue emission color different from the first color, and therefore has two emission colors. The light emitting element array 30GB is only required to be arranged according to the layout of the sub-pixels 201. For example, as depicted in FIGS. 9 and 10, the LED elements 50B and the LED elements 50G may alternately be arranged. FIG. 10 is a cross-sectional diagram for schematically explaining the light emitting element array 30GB in one example. As described above, the LED element 50B and the LED element 50G have a structure including the light emitting layer 46 emitting blue light (blue light emitting layer 46B) and a structure including the light emitting layer 46 emitting green light (green light emitting layer 46G), respectively. According to the light emitting device 10 of modification 2 presented in the example of FIG. 9, such two types of light emitting element arrays, i.e., the light emitting element arrays 30GB and 30R, are provided on the one drive substrate 20. Also in this case, the multiple light emitting element arrays 30 are provided on the one drive substrate 20 in the light emitting device 10 of the first embodiment. Accordingly, the advantageous effects explained in the above first embodiment can be offered.

### Modification 3

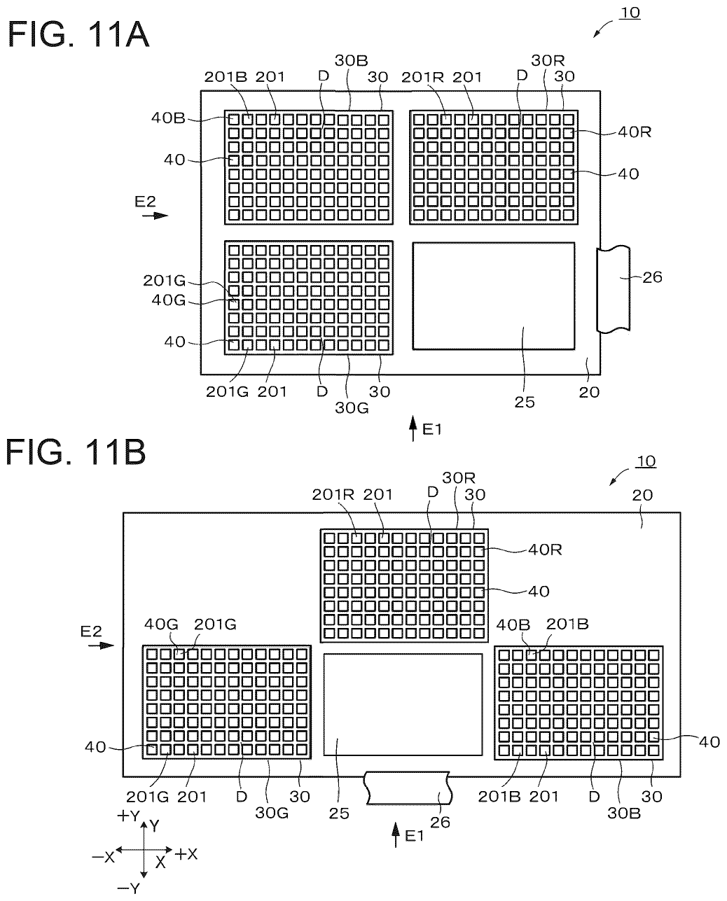

As depicted in FIG. 11A and FIG. 11B, the layout of the multiple light emitting element arrays 30 according to the light emitting device 10 of the first embodiment is not limited to the pattern of a single-line arrangement (single-line layout) example. For example, the layout of the multiple light emitting element arrays 30 may be an L-shaped arrangement pattern as depicted in FIG. 11A, or a V-shaped (delta-shaped) arrangement pattern as depicted in in FIG. 11B. This mode will be referred to as modification 3 of the first embodiment. According to the example in FIG. 11A, the three types of light emitting element arrays 30B, 30R, and 30G and the auxiliary circuit 25 are formed at predetermined positions of the drive substrate 20. In this configuration, the three types of light emitting element arrays 30B, 30R, and 30G are arranged in an L shape. According to the example in FIG. 11A, the other two light emitting element arrays 30 (the light emitting element arrays 30G and 30R in the example of FIG. 11A) are arranged in such a manner as to be located adjacently to the one light emitting element array 30 (the light emitting element array 30B in the example of FIG. 11A) on (the −Y direction side and the +X direction side) in a planar view of the drive substrate 20. According to the example in FIG. 11B, the three light emitting element arrays 30 (the light emitting element arrays 30R, 30G, and 30R in the example of FIG. 11A) are arranged in such a manner as to form a triangle by connection of centers of the respective light emitting element arrays 30 in a plan view of the drive substrate 20. Moreover, according to the example in FIG. 11B, the three types of light emitting element arrays are arranged in a V shape (mountain shape) in such a manner as to be located adjacently to each other in three directions (the +X direction, the −X direction, and the +Y direction) with respect to the auxiliary circuit 25.

### Modification 4

According to the light emitting device 10 of the first embodiment depicted in the example of FIG. 1, the light emitting elements 40 provided for the sub-pixels 201 on each of the light emitting element arrays 30 are formed in such a manner as to have almost equalized resolution in a first direction and a second direction crossing at right angles. According to the example in FIG. 1, the multiple light emitting elements 40 provided on the light emitting element arrays 30 are formed in such a manner as to have almost equalized resolution in the vertical direction corresponding to the first direction (in FIG. 4, an extension direction of the data lines LD; Y-axis direction) and in the horizontal direction corresponding to the second direction (in FIG. 4, an extension direction of the scanning lines LS; X-axis direction).

According to the light emitting device 10 of the first embodiment, the sub-pixels 201 provided on each of the light emitting element arrays 30 may have different resolution for each of the vertical direction as the first direction and the horizontal direction as the second direction. This mode will be referred to as modification 4 of the first embodiment. Note that the resolution in the vertical direction is the number of the sub-pixels 201 in the vertical direction and also the number of the sub-pixels 201 arranged in a unit length. The resolution in the horizontal direction is the number of the sub-pixels 201 in the horizontal direction and also the number of the sub-pixels 201 arranged in a unit length.

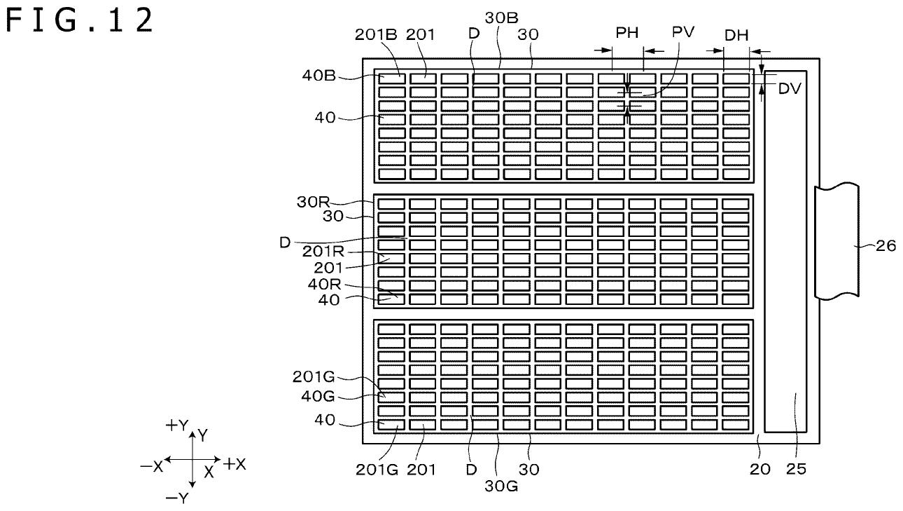

As depicted in FIG. 12, the light emitting device 10 according to modification 4 of the first embodiment can specifically be produced by setting a different value for each of a pitch PV of the light emitting elements 40 in the vertical direction (Y-axis direction) corresponding to the first direction and a pitch PH of the light emitting elements 40 in the horizontal direction (X-axis direction) corresponding to the second direction. According to the example of modification 4 depicted in FIG. 12, a size DV of each of the light emitting elements 40 in the first direction is smaller than a size DH of each of the light emitting elements 40 in the second direction. In addition, the pitch PV of each of the light emitting elements 40 in the first direction is smaller than the pitch PH of each of the light emitting elements 40 in the second direction. In this manner, the resolution of the sub-pixels 201 formed in the vertical direction on the light emitting element arrays 30 is raised higher than the resolution in the horizontal direction.

### Modification 5

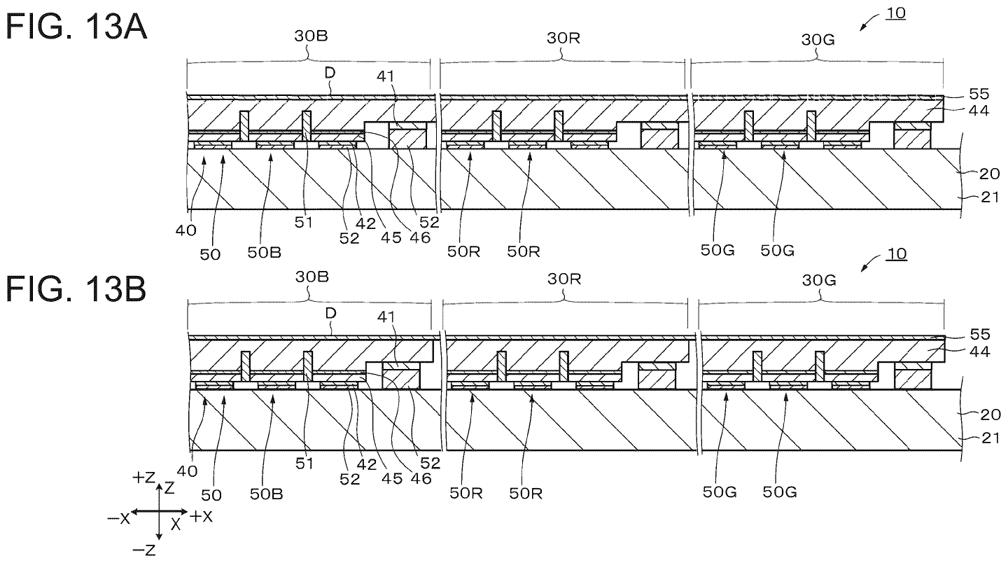

The light emitting element arrays 30 in the light emitting device 10 according to the example of the first embodiment depicted in FIG. 1 are separated from each other. However, the light emitting device 10 according to the first embodiment is not limited to the light emitting device 10 thus configured. For example, as depicted in FIG. 13A and FIG. 13B, the multiple light emitting element arrays 30 may be connected to each other. This mode will be referred to as modification 5 of the first embodiment. FIG. 13A and FIG. 13B are each a diagram depicting the light emitting device 10 according to one example of modification 5. In FIG. 13A, the multiple light emitting element arrays 30B, 30R, and 30G are connected to each other such that the first compound semiconductor layer 44 is shared by these arrays. In this manner, the multiple light emitting element arrays 30B, 30R, and 30G are integrated with each other as a whole.

In the case of the multiple light emitting element arrays 30 connected to each other, the structure for connecting the light emitting element arrays 30 is not limited to the example depicted in FIG. 13A. As depicted in FIG. 13B, a conductive layer 55 including conductive metal or the like may be provided on the first surface side of the light emitting element arrays 30B, 30R, and 30G as a common layer for the light emitting element arrays 30B, 30R, and 30G. In this case, the light emitting element arrays 30B, 30R, and 30G may be connected to each other via the conductive layer 55. Note that the conductive layer 55 may be provided in a case where the multiple light emitting element arrays 30B, 30R, and 30G are connected to each other via the first compound semiconductor layer 44 as a common layer for these arrays as depicted in FIG. 13A.

### Modification 6

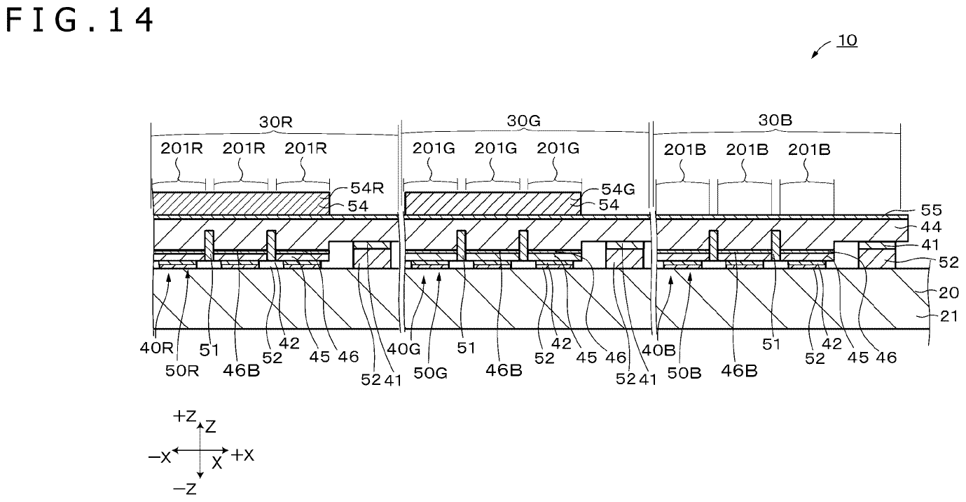

As depicted in an example of FIG. 14, a color conversion layer may be provided on the first surface side of the light emitting element arrays 30 in the light emitting device 10 of the first embodiment. This mode will be referred to as modification 6 of the first embodiment. FIG. 14 is a cross-sectional diagram depicting the light emitting device 10 according to one example of modification 6 of the first embodiment. Note that, while presented in the example of FIG. 14 is a case where the multiple light emitting element arrays 30 are connected to each other as explained in modification 5 described above, the light emitting element arrays 30 may be singulated as explained in the first embodiment with reference to FIG. 1 and other figures.

### (Light Emitting Element Array)

The light emitting elements 40 provided on the multiple light emitting element arrays 30 may generate rays of light each having a main wavelength in a different wavelength band, or may generate rays of light each having a main wavelength approximately in the same wavelength band. According to the example depicted in FIG. 14, the blue light emitting layer 46B emitting blue light is formed as the light emitting layer 46 of each of the light emitting elements 40 even for the light emitting element arrays 30B, 30R, and 30G corresponding to any of the sub-pixels 201B, 201R, and 201G.

### (Color Conversion Layer)

For example, the color conversion layer can be a quantum dot layer 54 or the like. The quantum dot layer 54 is a layer containing multiple quantum dots. For example, each of the quantum dots can have a core portion including a compound semiconductor, and a shell layer that includes a semiconductor or the like and that covers a circumferential surface of the core portion. According to the example in FIG. 14, the quantum dot layer 54 includes a red quantum dot layer 54R and a green quantum dot layer 54G. The red quantum dot layer 54R is provided for the light emitting element array 30R corresponding to the red sub-pixels 201R, while the green quantum dot layer 54G is provided for the light emitting element array 30G corresponding to the green sub-pixels. For the light emitting element array 30B corresponding to the blue sub-pixels 201B, it is preferable that a layer through which light is transmitted be provided at each of positions corresponding to positions where the quantum dot layers 54 are formed in the light emitting element arrays 30R and 30G. However, the layers through which light is transmitted are not depicted in FIG. 14 for convenience of explanation.

Note that, while FIG. 14 depicts the quantum dot layer 54 formed as a common layer for the multiple sub-pixels 201 provided on each of the light emitting element arrays 30, this configuration is presented only by way of example. The quantum dot layer 54 may be formed in an individually separated state for each of the sub-pixels 201. Moreover, the quantum dot layer 54 may be formed in an individually separated state for each of combinations of some of the sub-pixels 201. For example, the red quantum dot layer 54R may be formed in an individually separated state for each of the red sub-pixels 201. The red quantum dot layer 54R may be formed in a separated state for each set of the three adjoining red sub-pixels 201.

In the light emitting element array 30R corresponding to the red sub-pixels 201R, blue light generated from the blue light emitting layer 46B is converted into red light while passing through the red quantum dot layer 54R. In the light emitting element array 30G corresponding to the green sub-pixels 201G, blue light generated from the blue light emitting layer 46B is converted into green light while passing through the green quantum dot layer 54G. In the light emitting element array 30B corresponding to the blue sub-pixels 201B, blue light generated from the blue light emitting layer 46B is extracted.

### Modification 7

The light emitting elements 40 provided on at least the two different light emitting element arrays 30 of the light emitting device 10 according to the first embodiment may have different sizes (particularly areas of light emitting portions) for each of the light emitting element arrays 30 (not depicted). This mode will be referred to as modification 7 of the first embodiment. According to modification 7, in a case where luminance (brightness per unit area) of the light emitting elements 40 provided on the one light emitting element array 30 is lower than luminance of the light emitting elements 40 provided on the other light emitting element arrays 30, for example, the sizes of the light emitting elements 40 may be determined such that the size of the light emitting elements 40 having lower luminance becomes larger than the size of the light emitting elements 40 having higher luminance.

### 2 Second Embodiment

### [2-1 Configuration of Light Emitting Device]

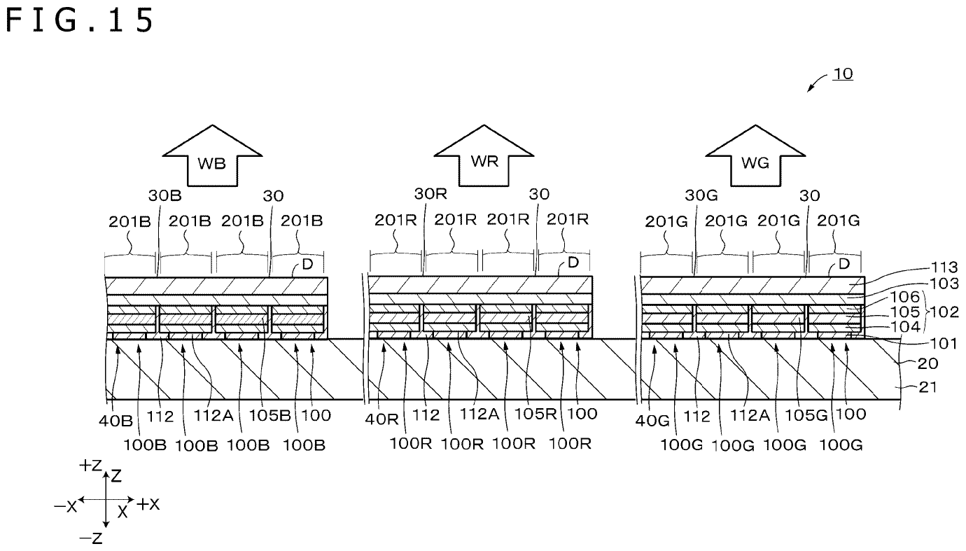

The light emitting device 10 according to the second embodiment includes the light emitting element arrays 30. According to the second embodiment, the multiple light emitting elements 40 provided on at least one of the light emitting element arrays 30 are constituted by multiple OLED elements 100 as depicted in FIG. 15. FIG. 15 is a cross-sectional diagram for explaining the light emitting device 10 according to one example of the second embodiment. The example depicted in FIG. 15 and other figures is a case where the light emitting elements 40 constituting all of the light emitting element arrays 30 provided on the drive substrate 20 are OLED elements. The light emitting device 10 according to the second embodiment is configured similarly to the light emitting device 10 according to the first embodiment except for the point that the light emitting elements 40 provided on the light emitting element arrays 30 are the OLED elements 100. Moreover, the types, the layout, and the like of the light emitting element arrays 30 included in the light emitting device 10 according to the second embodiment may be similar to those of the light emitting device 10 according to the first embodiment. Accordingly, other configurations of the light emitting elements 40 of the light emitting element array 30 (e.g., the pixel unit 14, the drive substrate 20, and the like) are not repeatedly explained. Modifications 2 to 7 of the first embodiment may also be applied to the second embodiment.

### (Light Emitting Element Array)

The light emitting device 10 according to the second embodiment has the multiple light emitting element arrays 30 on the drive substrate 20. Each of the light emitting element arrays 30 includes the OLED elements 100 as the light emitting elements 40.

According to the second embodiment, each of the OLED elements 100 provided on the light emitting element arrays 30 emits light corresponding to the sub-pixel 201. For example, in the light emitting element array 30R corresponding to the red sub-pixel 201R, each of the OLED elements 100 is configured to emit red light from the light extraction surface. The OLED elements 100 may have a layout similar to that of the first embodiment. In the example of FIG. 15, the OLED elements 100 are arranged in a matrix form. Each of the light emitting element arrays 30 has the light extraction surface D which is a surface facing in a direction from the drive substrate 20 toward the LED elements 100 (the +Z direction).

According to the example depicted in FIG. 15, OLED elements 100R emitting red light are provided on the light emitting element array 30R, OLED elements 100G emitting green light are provided on the light emitting element array 30G, and OLED elements 100B emitting blue light are provided on the light emitting element array 30B. Note that each of the OLED elements 100R, 100G, and 100B in the present description will collectively and simply be referred to as the OLED element 100 in a case where no distinction is particularly needed between the OLED elements 100R, 100G, and 100B.

### (Structure of OLED Element)

In each of the light emitting element arrays 30, the OLED elements 100 constituting the light emitting elements 40 are provided for the sub-pixels 201 with one-to-one correspondence.

As depicted in the example of FIG. 15, each of the OLED elements 100 includes a first electrode 101, an organic layer 102, and a second electrode 103. The first electrode 101, the organic layer 102, and the second electrode 103 are laminated in this order from the drive substrate 20 side in the direction from the second surface toward the first surface (the +Z direction)

### (First Electrode)

As depicted in FIG. 15, the multiple first electrodes 101 are provided on the first surface side of the drive substrate 20. The first electrodes 101 are electrically separated from each other by an insulation layer 112 described below, for each of the sub-pixels 201. The first electrodes 101 are anode electrodes. The first electrodes 101 may function as reflection layers as well. In this case, it is preferable that the first electrodes 101 have the highest possible reflectance. It is further preferable that each of the first electrodes 101 include a material having a high work function, to improve light emission efficiency. While the first electrodes 101 are each formed on the drive substrate 20 in the example depicted in FIG. 15, the first electrodes 101 are not required to have this structure. The first electrodes 101 may be included in the drive substrate 20. This is also applied to the insulation layer 112 described below. Moreover, each of the first electrodes 101 is electrically connected to a contact wiring portion of the drive substrate 20.

Each of the first electrodes 101 includes at least either one of a metal layer and a metal oxide layer. Each of the first electrode 101 may have a single layer film which is a metal layer or a metal oxide layer, or a laminated film which has both a metal layer and a metal oxide layer. In a case where each of the first electrodes 101 has the laminated film, the metal oxide layer may be provided on the organic layer 102 side, or the metal layer may be provided on the organic layer 102 side. It is preferable, however, that the metal oxide layer be provided on the organic layer 102 side to provide a layer having a high work function adjacently to the organic layer 102.

Each of the first electrodes 101 may include a reflection plate and a transparent conductive layer. For example, each of the first electrodes 101 having this configuration can be formed by providing a metal layer having light reflectivity as the reflection plate and by providing a metal oxide film having light transparency as the transparent conductive layer. Alternatively, each of the first electrodes 101 may be formed by a transparent conductive layer, and a reflection plate may be provided separately from the first electrodes 101.

For example, the metal layer contains at least one type of a metal element selected from a group including chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may contain at least the one type of the metal element described above as a constituent element of an alloy. Specific examples of the alloy include an aluminum alloy and a silver alloy. For example, specific examples of the aluminum alloy include AlNd and AlCu.

For example, the metal oxide layer contains at least one type of a material selected from a mixture of indium oxide and tin oxide (ITO), a mixture of indium oxide and zinc oxide (IZO), and titanium oxide (TiO).

### (Insulation Layer)

As depicted in FIG. 15, it is preferable that the insulation layer 112 of the light emitting device 10 be provided on the first surface side of the drive substrate 20. The insulation layer 112 is provided between the adjoining first electrodes 101, and electrically separates the first electrodes 101 for each of the light emitting elements 40 (OLED elements 100) (i.e., for each of the sub-pixels 201). Moreover, the insulation layer 112 has multiple openings 112A. The first surface of each of the first electrodes 101 (the surface facing the second electrode 103) is exposed through the corresponding opening 112A.

For example, the insulation layer 112 includes an organic material or an inorganic material. For example, the organic material contains at least either polyimide or acrylic resin. For example, the inorganic material contains at least one type selected from silicon oxide, silicon nitride, silicon oxynitride, and aluminum oxide.

### (Organic Layer)

Each of the organic layers 102 is provided between the first electrode 101 and the second electrode 103. Each of the organic layers 102 is provided as a layer electrically separated for the corresponding sub-pixel 201. According to the example of FIG. 15, each of the organic layers 102 is configured to be capable of emitting light corresponding to a color type of the corresponding sub-pixel 201. For example, each of the OLED elements 100R provided on the light emitting element array 30R is configured to be capable of emitting red light. Each of the OLED elements 100B provided on the light emitting element array 30B is configured to be capable of emitting blue light. Each of the OLED elements 100G provided on the light emitting element array 30G is configured to be capable of emitting green light.

However, this configuration does not exclude such a configuration which includes the organic layers 102 emitting light colors other than red, blue, and green. For example, each of the organic layers 102 may be configured to be capable of emitting white light.

As depicted in FIG. 15, in a case where the organic layers 102 are formed as layers separated for each of the sub-pixels 201, a layer individually separating the organic layers 102 for each of the OLED elements 100 may be provided between the adjoining organic layers 102. The layer for individually separating the organic layers 102 may be the insulation layer 112 as depicted in FIG. 15, or may be a layer that is different from the insulation layer 112 and has insulation properties.

For example, as depicted in FIG. 15, each of the organic layers 102 has such a structure where a hole injection transport layer 104, an organic light emitting layer 105, and an electron transport layer 106 are provided in this order from the first electrode 101 toward the second electrode 103. An electron injection layer may be provided between the electron transport layer 106 and the second electrode 103. The electron injection layer is a layer for increasing electron injection efficiency. For example, a material of the electron injection layer can be a simple substance of alkali metal or alkali earth metal, such as lithium and lithium fluoride, or a compound containing these. Note that the configuration of the organic layers 102 is not limited to this example. The layers other than the organic light emitting layer 105 are provided as necessary.

The hole injection transport layer 104 has such a structure where a hole injection layer and a hole transport layer are provided in this order from the first electrode 101 toward the second electrode 103.

The hole injection layer is a buffer layer provided for increasing efficiency of hole injection into the organic light emitting layer 105, and also for reducing leaks. For example, a material of the hole injection layer can be hexaazatriphenylene (HAT). The hole transport layer is a layer for increasing efficiency of hole transport to the organic light emitting layer 105. For example, a material of the hole transport layer can be N,N′-di(1-naphthyl)-N,N′-diphenyl-1,1′-biphenyl-4, or 4′-diamine(α-NPD).

The electron transport layer 106 is a layer for increasing efficiency of electron transport to the organic light emitting layer 105. For example, a material of the electron transport layer 106 can be aluminum quinolinol, bathophenanthroline, or the like.

Each of the organic light emitting layers 105 is a layer for forming light by recombination between electrons and holes caused by an electric field applied thereto. Each of the organic light emitting layers 105 is a layer containing an organic light emitting material. The organic light emitting layer 105 provided on each of the OLED elements 100R is a red light emitting layer 105R. The organic light emitting layer 105 provided on each of the OLED elements 100B is a blue light emitting layer 105B. The organic light emitting layer 105 provided on each of the OLED elements 100G is a green light emitting layer 105G.

For example, the red light emitting layer 105R may be a layer containing a red light emitting material, a hole transport material, an electron transport material, and both charge transport materials. The red light emitting material may be either a fluorescence material or a phosphorescence material. Specifically, for example, the red light emitting layer may include a material produced by mixing 30 percent by weight of 2,6-bis[(4′-methoxydiphenylamino) styril]-1,5-dicyanonaphthalene (BSN) with 4,4-bis(2,2-diphenylbinine)biphenyl (DPVBi).

For example, the blue light emitting layer 105B may be a layer containing a blue light emitting material, a hole transport material, an electron transport material, and both charge transport materials. The blue light emitting material may be either a fluorescence material or a phosphorescence material. Specifically, for example, the blue light emitting layer 105B includes a material produced by mixing 2.5 percent by weight of 4,4′-bis[2-{4′-(N,N-diphenylamino)phenyl}vinyl]biphenyl (DPAVBi) with DPVBi.

For example, the green light emitting layer 105G may be a layer containing a green light emitting material, a hole transport material, an electron transport material, and both charge transport materials. The green light emitting material may be either a fluorescence material or a phosphorescence material. Specifically, for example, the green light emitting layer 105B may include a material produced by mixing 5 percent by weight of coumarin 6 with DPVBi.

### (Second Electrode)

The second electrode 103 is provided in such a manner as to face the first electrodes 101. The second electrode 103 is provided as a common electrode for the sub-pixels 201. The second electrode 103 is a cathode electrode. It is preferable that the second electrode 103 be a transparent electrode through which light generated at the organic layer 102 is transmitted. Examples of the transparent electrode referred to herein include an electrode constituted by a transparent conductive layer, and an electrode having a laminated structure (not depicted) having a transparent conductive layer and a semi-transparent reflective layer.

The second electrode 103 includes at least either one of a metal layer and a metal oxide layer. More specifically, the second electrode 103 has a single layer film which is a metal layer or a metal oxide layer, or a laminated film which has both a metal layer and a metal oxide layer. In a case where the second electrode 103 has the laminated film, the metal layer may be provided on the organic layer 102 side, or the metal oxide layer may be provided on the organic layer 102 side.

It is preferable that the transparent conductive layer include a transparent conductive material having excellent light transparency and a low work function. For example, the transparent conductive layer can include metal oxide. Specifically, for example, the transparent conductive layer can contain at least one type of a material selected from a mixture of indium oxide and tin oxide (ITO), a mixture of indium oxide and zinc oxide (IZO), and zinc oxide (ZnO).

For example, the semi-transparent reflective layer can include a metal layer. Specifically, for example, the semi-transparent reflective layer can include a material containing at least one type of a metal element selected from a group including magnesium (Mg), aluminum (Al), silver (Ag), gold (Au), and copper (Cu). The metal layer may contain at least the one type of a metal element described above, as a constituent element of an alloy. Specific examples of the alloy include an MgAg alloy, an AgPdCu alloy, and the like.

The second electrodes 103 may extend outward from an outer circumferential end of the light emitting element array 30 and be connected to a pad (not depicted) formed on the drive substrate 20. Moreover, an auxiliary electrode connected to a pad may be provided on the drive substrate 20 and be connected to the second electrode 103. The second electrode 103 may be electrically connected to various circuits formed on the drive substrate 20 side via the pad and the auxiliary electrode. Note that FIG. 15 does not depict the pad and the auxiliary electrode which will be described below, for convenience of explanation.

### (Protection Layer)

A protection layer 113 is formed on the first surface of the second electrode 103. The protection layer 113 is formed in such a manner as to cover the multiple OLED elements 100. The protection layer 113 blocks contact between the OLED elements 100 and the outside air, and reduces entrance of moisture from an outside environment into the OLED elements 100. Moreover, in a case where the semi-transparent reflective layer including a metal layer is provided on the second electrode 103, the protection layer 113 may have a function of reducing oxidation of this metal layer.

The protection layer 113 includes an insulating material. For example, the insulating material can be a thermosetting resin or the like. Alternatively, the insulating material may be SiO, SiON, AlO, TiO, or the like. In this case, for example, the protection layer 113 can be a CVD film containing SiO, SiON, or the like, or an ALD film containing AlO, TiO, SiO, or the like. The protection layer 113 may be a single layer, or a layer in a state of a lamination of multiple layers. Note that the CVD film refers to a film produced by use of chemical vapor deposition. The ALD film refers to a film produced by use of atomic layer deposition.

### [2-2 Operation and Advantageous Effects]

According to the light emitting device 10 of the second embodiment, the multiple light emitting element arrays 30 are provided on the one drive substrate 20 as depicted in FIG. 15. Accordingly, advantageous effects similar to those of the light emitting device 10 of the first embodiment can be offered by the light emitting device 10 according to the second embodiment. Described next will be a modification of the light emitting device 10 according to the second embodiment.

### (2-3 Modification)

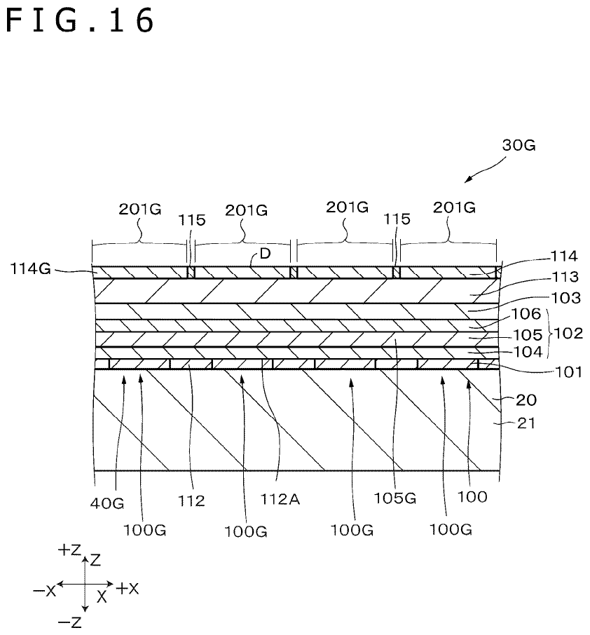

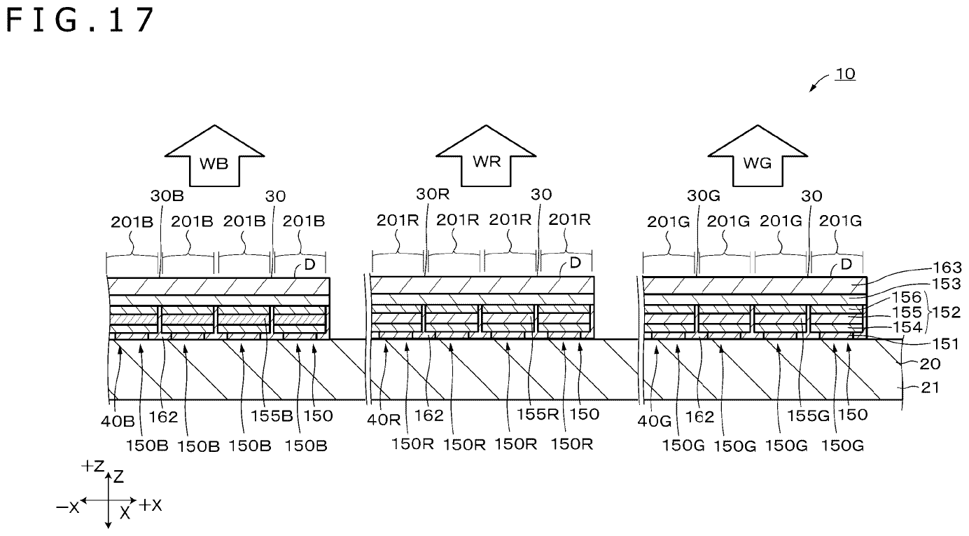

As depicted in FIG. 16, the organic layer 102 of the OLED elements 100 included in the light emitting element array 30 of the light emitting device 10 of the second embodiment may be provided as a common layer for the multiple OLED elements 100. This mode will be referred to as a modification of the second embodiment. FIG. 16 is a cross-sectional diagram for explaining the OLED elements 100 included in the light emitting device 10 according to one example of the modification of the second embodiment. FIG. 16 depicts an example where the organic layer 102 of the light emitting element array 30G are provided as a common layer for the multiple OLED elements 100. The light emitting element array 30G as an example of the light emitting element array 30 used in the modification of the second embodiment will be explained with reference to FIG. 17.

### (Organic Layer)

It is preferable that the organic layer 102 be configured to emit light corresponding to the OLED elements 100. As described above, the organic layer 102 has such a structure where the hole injection transport layer 104, the organic light emitting layer 105, and the electron transport layer 106 are provided in this order from the first electrode 101 toward the second electrode 103. It is preferable that the organic light emitting layer 105 for the OLED elements 100G be the green light emitting layer 105G.

### (Color Filter)

As depicted in FIG. 16, color filters 114 may be provided on the first surface side (upper side, +Z side) of the protection layer 113. Each of the color filters 114 depicted in the example of FIG. 17 is an on-chip color filter (OCCF). The color filters 114 are provided in correspondence with the color type of the sub-pixels 201. Green color filters (green filters 114G) are preferably used as the color filters 114 of the light emitting element array 30G. The color filters 114 provided on the light emitting element array 30 can further improve color purity. Note that a flattened layer (not depicted) may be provided on the first surface side of the color filters 114.

### (Light Shield Layer)

A light shield layer 115 may be provided on the first surface side (upper side, +Z side) of the protection layer 113. The light shield layer 115 is provided between the adjoining OLED elements 100 to divide the sub-pixels 201 into individual sections. Moreover, according to the example in FIG. 16, the light shield layer 115 is provided between the adjoining color filters 114. For example, the light shield layer 115 can be a black matrix or the like.

Described above with reference to FIG. 16 has been the light emitting element array 30G adopted in the modification of the second embodiment. The modification of the second embodiment is also applicable to the light emitting element arrays 30R and 30B similarly to the light emitting element array 30G. However, unlike the light emitting element array 30G, the light emitting element arrays 30R and 30B in the modification of the second embodiment have the organic light emitting layers 105 constituting a red light emitting layer and a blue light emitting layer, respectively. Moreover, in a case where the color filters 114 are provided for the light emitting element arrays 30R and 30B, red color filters (red filters) are preferably used as the color filters 114 of the light emitting element array 30R. Blue color filters (blue filters) are preferably used as the color filters 114 of the light emitting element array 30B.

The structure of the light emitting element array 30 depicted in the modification of the second embodiment may be applied to all the types of the light emitting element arrays 30 as a common structure, or may be applied to only some of the types of the light emitting element arrays 30. For example, the modification is also applicable to the light emitting element arrays 30B, 30R, and 30G. Alternatively, the modification may be applied to only the light emitting element array 30G, while the organic layer 102 may be separated for each of the OLED elements 100 of the light emitting element arrays 30R and 30G as described above with reference to FIG. 15.

### 3 Third Embodiment

### [3-1 Configuration of Light Emitting Device]

As depicted in an example of FIG. 17, the light emitting device 10 according to the third embodiment includes the light emitting element arrays 30. The multiple light emitting elements 40 provided on at least one of the light emitting element arrays 30 are multiple quantum dot light emitting elements 150 as depicted in the example of FIG. 17. The example depicted in FIG. 17 and other figures is a case where the light emitting elements 40 constituting all of the light emitting element array 30 provided on the drive substrate 20 are quantum dot light emitting elements. The light emitting device 10 according to the third embodiment is configured similarly to the light emitting devices 10 according to the first and second embodiments except for the point that the light emitting elements 40 provided on the light emitting element arrays 30 are the quantum dot light emitting elements 150. Moreover, the types, the layout, and the like of the light emitting element arrays 30 included in the light emitting device 10 according to the third embodiment may be similar to those of the light emitting device 10 according to the first and second embodiments. Accordingly, other configurations of the light emitting elements 40 (e.g., the pixel unit 14, the drive substrate 20, and the like) are not repeatedly explained. Modifications 2 to 7 of the first embodiment may also be applied to the third embodiment. Similarly, the modification of the second embodiment may also be applied to the third embodiment.

According to the example depicted in FIG. 17, quantum dot light emitting elements 150R emitting red light are provided on the light emitting element array 30R, quantum dot light emitting elements 150G emitting green light are provided on the light emitting element array 30G, and quantum dot light emitting elements 150B emitting blue light are provided on the light emitting element array 30B. Note that each of the quantum dot light emitting elements 150R, 150G, and 150B in the present description will collectively and simply be referred to as the quantum dot light emitting element 150 in a case where no distinction is particularly needed between the quantum dot light emitting elements 150R, 150G, and 150B.

### (Quantum Dot Light Emitting Element)

As depicted in the example of FIG. 17, each of the quantum dot light emitting elements 150 includes a first electrode 151, a light emitting layer 152, and a second electrode 153. The first electrode 151, the light emitting layer 152, and the second electrode 103 are laminated in this order on the drive substrate 20 side in the direction from the second surface toward the first surface (the +Z direction).

The first electrode 151 and the second electrode 153 may be configured similarly to the first electrode 101 and the second electrode 103 of each of the OLED elements 100 according to the second embodiment. Moreover, an insulation layer 162 is formed between the adjoining first electrodes 151. A protection layer 163 is formed on the first surface side of the second electrode 153. The insulation layer 162 and the protection layer 163 may be configured similarly to the insulation layer 112 and the protection layer 113 of the OLED elements 100 according to the second embodiment.

### (Light Emitting Layer)

Each of the light emitting layers 152 is provided between the first electrode 151 and the second electrode 153. The light emitting layers 152 are provided as layers electrically separated for each of the sub-pixels 201. According to the example of FIG. 15, each of the light emitting layers 152 is configured to be capable of emitting light according to the color type of the corresponding sub-pixel 201. Each of the quantum dot light emitting elements 150R provided on the light emitting element array 30R is configured to be capable of emitting red light. Each of the quantum dot light emitting elements 150B provided on the light emitting element array 30B is configured to be capable of emitting blue light. Each of the quantum dot light emitting elements 150G provided on the light emitting element array 30G is configured to be capable of emitting green light. However, this configuration does not exclude such a configuration which includes the light emitting layers 152 having emission colors other than red, blue, and green.

In a case where the light emitting layers 152 are formed as layers separated for each of the sub-pixels 201, a layer individually separating the light emitting layers 152 for each of the quantum dot light emitting elements 150 may be provided between the adjoining light emitting layers 152 similarly to the organic layers 102 of the OLED elements 100 according to the second embodiment described above. According to the example of FIG. 17, the insulation layer 162 separates the light emitting layers 152 for each of the quantum dot light emitting elements 150.

Each of the light emitting layers 152 is a layer having a quantum dot layer 155. For example, as depicted in FIG. 17, each of the light emitting layers 152 has such a structure where a hole injection transport layer 154, the quantum dot layer 155, and an electron transport layer 156 are provided in this order from the first electrode 151 toward the second electrode 153. The hole injection transport layer 154 and the electron transport layer 156 may have configurations similar to those of the hole injection transport layer 104 and the electron transport layer 106 included in the organic layer 102 of each of the OLED elements 100 according to the second embodiment described above.

### (Quantum Dot Layer)

Each of the quantum dot layers 155 may be configured similarly to the quantum dot layers 54 explained in modification 7 of the first embodiment. However, according to the example in FIG. 17, red quantum dot layers 155R are provided as the quantum dot layers 155 of the quantum dot light emitting elements 150R. Blue quantum dot layers 155B are provided as the quantum dot layers 155 of the quantum dot light emitting elements 150B. Green quantum dot layers 155G are provided as the quantum dot layers 155 of the quantum dot light emitting elements 150G.

### [3-2 Operation and Advantageous Effects]

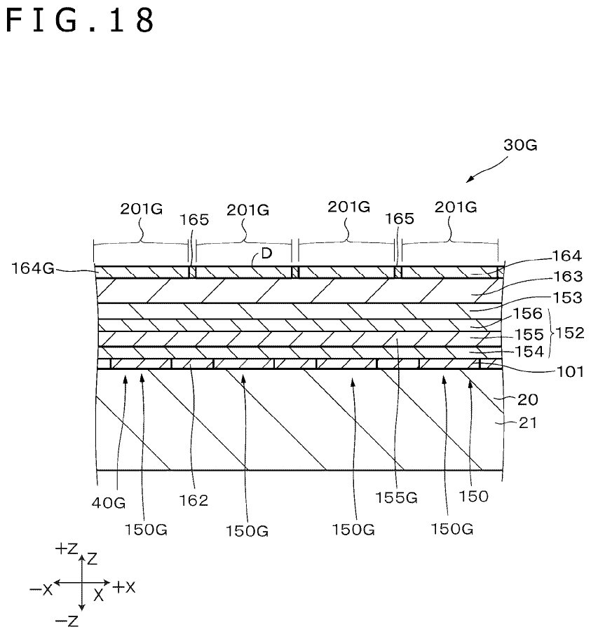

According to the light emitting device 10 of the third embodiment, the multiple light emitting element arrays 30 are provided on the one drive substrate 20 as depicted in FIG. 18. Accordingly, advantageous effects similar to those of the light emitting device 10 of the first embodiment can be offered by the light emitting device 10 according to the third embodiment.

Described next will be a modification of the light emitting device 10 according to the third embodiment.

### (3-3 Modification)

As depicted in FIG. 18, the light emitting layer 152 of the quantum dot light emitting elements 150 included in the light emitting element array 30 of the light emitting device 10 according to the third embodiment may be provided as a common layer for the multiple quantum dot light emitting elements 150. This mode will be referred to as a modification of the third embodiment. FIG. 18 is a cross-sectional diagram for explaining the quantum dot light emitting elements 150 included in the light emitting device 10 according to one example of the modification of the third embodiment. FIG. 18 depicts an example where the light emitting layer 152 of the light emitting element array 30G is provided as a common layer for the multiple quantum dot light emitting elements 150. The light emitting element array 30G as an example of the light emitting element array 30 used in the modification of the second embodiment will be described with reference to FIG. 18.

### (Light Emitting Layer)

It is preferable that the light emitting layer 152 be configured to emit light corresponding to the quantum dot light emitting elements 150. As described above, the light emitting layer 152 has such a structure where the hole injection transport layer 154, the quantum dot layer 155, and the electron transport layer 156 are provided in this order from the first electrode 151 toward the second electrode 153. It is preferable that the quantum dot layer 155 of the quantum dot light emitting elements 150G constitute the green quantum dot layer 155G.

### (Color Filter and Light Shield Layer)

As depicted in FIG. 18, color filters 164 may be provided on the light emitting element array 30G according to the modification of the third embodiment. The color filters 164 may be configured similarly to the color filters 114 explained in the modification of the second embodiment. Moreover, a light shield layer 165 may be provided on the light emitting element array 30G in the modification of the third embodiment. The color filters 164 and the light shield layer 165 may be configured similarly to the color filters 114 and the light shield layer 115 explained in the modification of the second embodiment. Green color filters (green filters 164G) are preferably employed as the color filters 164 of the light emitting element array 30G.

Described above with reference to FIG. 18 has been the light emitting element array 30G used in the modification of the third embodiment. The modification of the third embodiment is also applicable to the light emitting element arrays 30R and 30B similarly to the light emitting element array 30G. However, unlike the light emitting element array 30G, the light emitting element arrays 30R and 30B in the modification of the third embodiment have the quantum dot layers 155 constituting a red quantum dot layer and a blue quantum dot layer, respectively. Moreover, in a case where the color filters 164 are provided for the light emitting element arrays 30R and 30B, red color filters (red filters) are preferably employed as the color filters 164 of the light emitting element array 30R as explained in the modification of the second embodiment. Blue color filters (blue filters) are preferably employed as the color filters 114 of the light emitting element array 30B.

The structure of the light emitting element array 30 explained in the modification of the third embodiment may be applied to all the types of the light emitting element arrays 30 or may be applied to only some of the types of the light emitting element arrays 30 as in the modification of the second embodiment.

Note that the quantum dot layer 155 depicted in FIG. 18 is formed as a common layer for the multiple sub-pixels 201 provided on the corresponding light emitting element array 30G. Moreover, the quantum dot layers 155 in FIG. 17 referred to above are formed in an individually separated state for each of the sub-pixels 201. These configurations are presented only by way of example. The quantum dot layers 155 may be formed in an individually separated state for each of combinations of some of the sub-pixels 201. For example, the quantum dot layers 155 may be formed in an individually separated state for each of the green sub-pixels 201G. The quantum dot layers 155 may be formed in a separated state for each combination constituted by three adjoining ones of the green sub-pixels 201G. These are also applied to the red sub-pixels 201R and the blue sub-pixels 201B.

### 4 Fourth Embodiment

### [4-1 Configuration of Light Emitting Device]

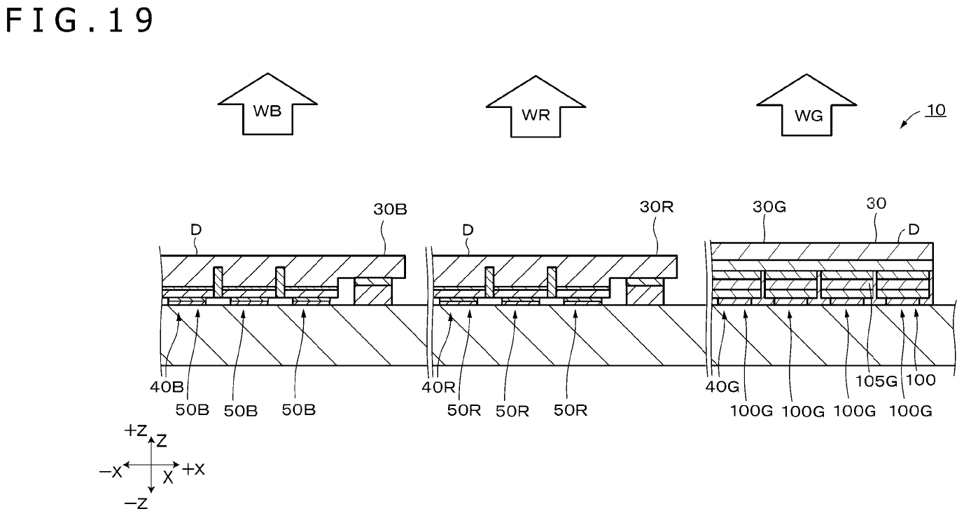

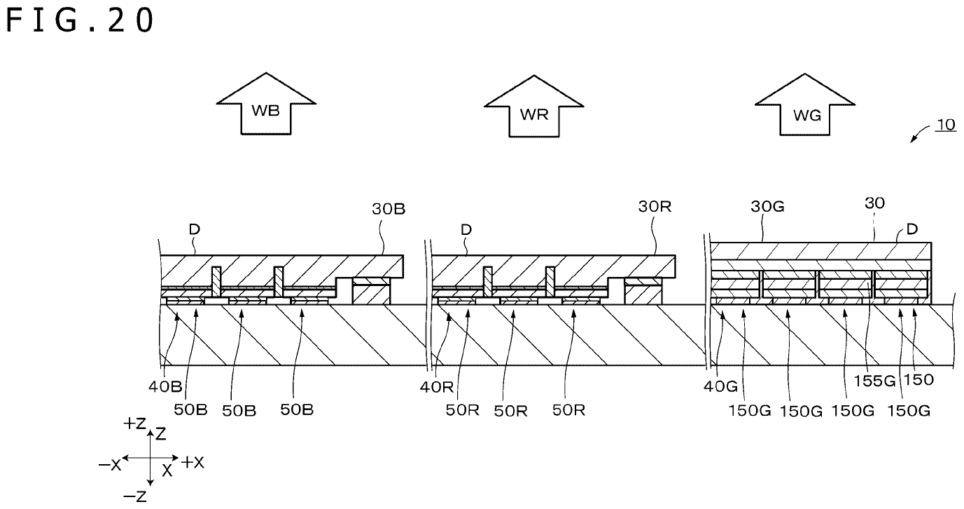

As depicted in FIGS. 19 and 20, the multiple light emitting element arrays 30 included in the light emitting device 10 according to the fourth embodiment are constituted by a combination of the light emitting element arrays 30 explained in the first to third embodiment. FIGS. 19 and 20 are diagrams for explaining the light emitting device 10 in one example of the fourth embodiment. Configurations in the fourth embodiment other than those of the combination of the light emitting element arrays 30 may be similar to the corresponding configurations in the first to third embodiments, and therefore will not be repeatedly explained. According to the light emitting device 10 in the fourth embodiment, the light emitting elements 40 provided on at least the two light emitting element arrays 30 are selected from a group including an LED element, an OLED element, and a quantum dot light emitting element, and also are elements of types different from each other.

In the example depicted in FIG. 19, the light emitting device 10 according to the fourth embodiment includes the LED elements 50 as the light emitting elements 40 provided on at least one of the light emitting element arrays 30, and the OLED elements 100 as the light emitting elements 40 provided on at least one of the other light emitting element arrays 30. The light emitting element array 30 including the LED elements 50 is formed similarly to the light emitting element arrays 30 explained in the first embodiment. The light emitting element array 30 including the OLED elements 100 is formed similarly to the light emitting element arrays 30 explained in the second embodiment.

According to the example depicted in FIG. 19, the light emitting element array 30R having a red emission color and the light emitting element array 30B having a blue emission color each include the LED elements 50, while the light emitting element array 30G having a green emission color includes the OLED elements 100.

According to the fourth embodiment, at least one of the multiple light emitting element arrays 30 may include the quantum dot light emitting elements 150 presented in the third embodiment, while at least one of the other light emitting element arrays 30 may include elements of types other than the quantum dot light emitting elements 150 (e.g., the LED elements 50, the OLED elements 100, or the like) as depicted in FIG. 20.

According to the example depicted in FIG. 20, the light emitting element array 30R and the light emitting element array 30B each include the LED elements 50, while the light emitting element array 30G includes the quantum dot light emitting elements 150.

### [4-2 Operation and Advantageous Effects]

According to the light emitting device 10 of the fourth embodiment, the multiple light emitting element arrays 30 are provided on the one drive substrate 20 as depicted in FIGS. 19 and 20. Accordingly, advantageous effects similar to those of the light emitting device 10 of the first embodiment can be offered by the light emitting device 10 according to the fourth embodiment.

### 5 Fifth Embodiment

### [5-1 Configuration of Light Emitting Device]

The light emitting device 10 according to the fifth embodiment includes the light emitting element arrays 30 similarly to the light emitting devices 10 of the first to fourth embodiments. According to the light emitting device 10 of the fifth embodiment, the optical system 210 may be provided above the light extraction surface D (first surface) of the light emitting element arrays 30 as depicted in FIG. 21. The light emitting device 10 according to the fifth embodiment may have configurations similar to the corresponding configurations of the light emitting devices 10 according to the first to fourth embodiments (e.g., the drive substrate 20, the light emitting element arrays 30, and the like) except for the configuration of the optical system 210 provided as above. Accordingly, the configurations other than the optical system 210 are not repeatedly explained. The respective modifications described in modifications 1 to 7 of the first embodiment, the modification in the second embodiment, and the modification in the third embodiment may also be applied to the light emitting device 10 according to the fifth embodiment. The light emitting device 10 according to the fifth embodiment depicted in FIG. 21 is an example which includes the optical system 210 provided on the first surface side of the light emitting element arrays 30 of the light emitting device 10 according to the first embodiment. Note that FIG. 21 is a diagram for schematically explaining a state of the light emitting device 10 which has a visual line direction of an arrow E1 in FIG. 1, and corresponds to a front diagram schematically depicting the light emitting device 10 according to the fifth embodiment. Note that the auxiliary circuit 25 and the FPC 26 are not depicted in FIG. 21 for convenience of explanation. As in FIG. 21, the auxiliary circuit 25 and the FPC 26 are not depicted in FIGS. 22 to 26 for convenience of explanation.

In the light emitting device 10 depicted in FIG. 21, the light emitting element arrays 30R, 30B, and 30G corresponding to red, blue, and green, respectively, are arranged in a line on the one drive substrate 20. The optical system 210 is provided in such a manner as to cover the light emitting element arrays 30 thus arranged.

### (Optical System)

The optical system 210 combines rays of light emitted from the respective light extraction surfaces D of the multiple light emitting element arrays 30. The optical system 210 has at least any one of a mirror and a prism. According to the example of FIG. 21, the optical system 210 has a mirror 212 and a prism 211. In this example, the mirror 212 has a mirror 212B1 and a mirror 212G1.

The mirror 212B1 is disposed on the light extraction surface D side of the light emitting element array 30B, the mirror 212G1 is disposed on the light extraction surface D side of the light emitting element array 30G, and the prism 211 is provided on the light extraction surface D side of the light emitting element array 30R. The mirror 212B1 reflects blue light WB generated by the light emitting element array 30. At this time, the blue light WB traveling in the +Z direction is directed toward the red light WR side (prism 211 side), and travels in the +X direction. The mirror 212G1 reflects green light WG generated by the light emitting element array 30G. At this time, the green light WG traveling in the +Z direction is directed toward the red light WR side (prism 211 side), and travels in the −X direction. The prism 211 depicted in the example of FIG. 21 is a cross prism which changes traveling directions of the blue light WB and the green light WG. The prism 211 allows the red light WR to pass through it. The traveling directions of the blue light WB and the green light WG are switched from the +X direction to the +Z direction and from the −X direction to the +Z direction, respectively, within the prism 211. Thereafter, the blue light WB and the green light WG are combined with the red light WR that is emitted from the light extraction surface D side of the light emitting element array 30R, passes through the prism 211, and travels in the +Z direction. The light produced by combining the red light WR, the blue light WB, and the green light WG (combined light) is emitted in a direction away from the first surface side (the +Z direction). Note that FIG. 21 indicates, by solid lines, traveling routes of the red light WR, the blue light WB, and the green light WG traveling within the optical system 210. These lines are similarly applied to FIGS. 22 to 26.

In addition, it is preferable that the light emitting device 10 according to the fifth embodiment include a correction unit (not depicted) which corrects a difference in optical path length (optical distance) between the blue light WB, the red light WR, and the green light WG. It is assumed that the optical distance refers to a product of a light traveling distance and a refractive index. Note that this definition is also applied to modifications 1 to 5 of the fifth embodiment described below.

### [5-2 Operation and Advantageous Effects]

Advantageous effects similar to those of the light emitting device 10 of the first embodiment can be offered by the light emitting device 10 according to the fifth embodiment. Moreover, the light emitting device 10 according to the fifth embodiment which includes the optical system 210 is capable of presenting full-color display. Further, according to the light emitting device 10 of the fifth embodiment, the multiple light emitting element arrays 30 are provided on the one drive substrate 20. Accordingly, the mirror 212 and the prism 211 constituting the optical system 210 can easily be positioned with respect to the light emitting element arrays 30.

Described next will be modifications of the light emitting device 10 according to the fifth embodiment.

### 5-3 Modifications

### Modification 1

As depicted in FIG. 22, the optical system 210 according to the fifth embodiment may be configured to emit combined light in a planar direction toward the light extraction surface D (X-axis direction in FIG. 22). FIG. 22 is a diagram for schematically explaining a state of the light emitting device 10 which has a visual line direction of the arrow E1 in FIG. 1, and corresponds to a front diagram schematically depicting the light emitting device 10 according to the fifth embodiment.

### (Optical System)

The optical system 210 includes the mirror 212B1, a mirror 212R1, and the mirror 212G1 as three mirrors of the mirror 212. Each of the mirrors 212 is disposed on the light extraction surface D side of the corresponding light emitting element array 30. The mirror 212B1 reflects the blue light WB generated by the light emitting element array 30B. The mirror 212R1 reflects the red light WR generated by the light emitting element array 30. The mirror 212B1 allows the red light WR and the green light WG to pass through it. The mirror 212R1 allows the green light WG to pass through it. The mirror 212G1 reflects the green light WG generated by the light emitting element array 30. The mirror 212 in the optical system 210 is arranged in such a manner as to equalize the traveling directions of the blue light WB, the red light WR, and the green light WG. According to the example of FIG. 22, each of the blue light WB, the red light WR, and the green light WG travels in the +Z direction, and reflects in a direction from the light emitting element array 30G toward the light emitting element array 30B (the −X direction in FIG. 22) to form combined light of the blue light WB, the red light WR, and the green light WG on the traveling route of the blue light WB in the −X direction. Thereafter, the combined light is emitted in the −X direction.

The light emitting device 10 according to modification 1 of the fifth embodiment which includes the optical system 210 is capable of presenting full-color display similarly to above.

According to the light emitting device 10 of the fifth embodiment and the light emitting device 10 of modification 1 of the fifth embodiment, the light emitting element arrays 30 are arranged in a layout of one line as depicted in FIGS. 21 and 22. The layout of the light emitting element arrays 30 included in the light emitting device 10 according to the fifth embodiment is not limited to these examples. For example, as will be explained below in modifications 2 to 5 of the fifth embodiment, the multiple light emitting element arrays 30 may have an L-shaped arrangement pattern as depicted in FIG. 11A or a V-shaped arrangement pattern as depicted in in FIG. 11B as in modification 4 of the first embodiment. According to the fifth embodiment, full-color display is achievable by the configuration of the optical system 210 corresponding to the layout even in a pattern different from the pattern of the one-line layout of the light emitting element arrays, 30 as will be described in modifications 2 to 5.

### Modification 2

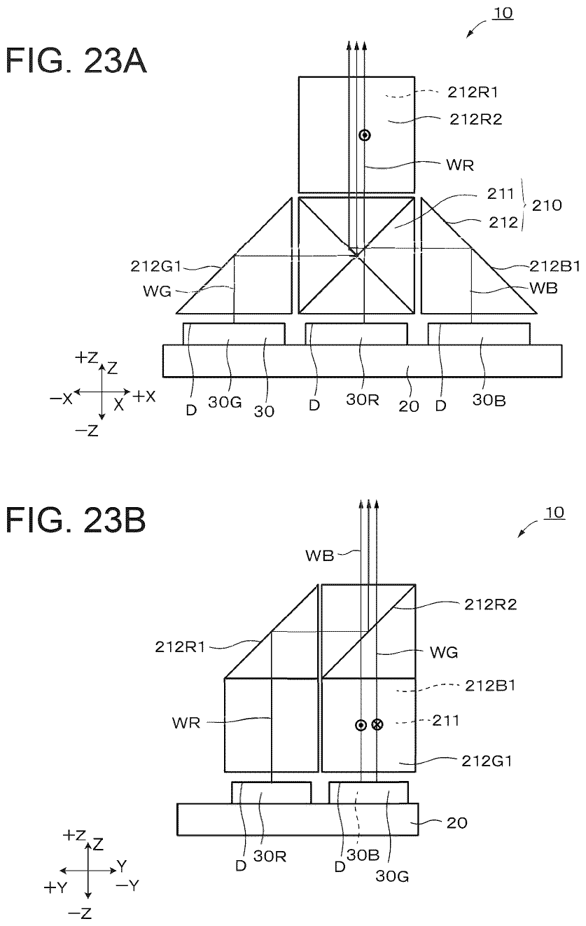

The light emitting device 10 according to modification 2 of the fifth embodiment has a V-shaped arrangement pattern for the layout of the light emitting element arrays 30 as depicted in FIG. 11B, and includes the optical system 210 above the light emitting element arrays 30. As depicted in FIG. 23A and FIG. 23B, the optical system 210 is configured to emit combined light in a direction away from the light extraction surface D. FIG. 23A is a diagram for schematically explaining a state of the light emitting device 10 which has a visual line direction of the arrow E1 in FIG. 11B, and corresponds to a front diagram schematically depicting the light emitting device 10 according to modification 2 of the fifth embodiment. FIG. 23B is a diagram for schematically explaining a state of the light emitting device 10 which has a visual line direction of an arrow E2 in FIG. 11B, and corresponds to a side diagram schematically depicting the light emitting device 10 according to modification 2 of the fifth embodiment.

### (Optical System)

The optical system 210 has the mirror 212 and the prism 211. As depicted in FIG. 23A and FIG. 23B, the optical system 210 has the mirror 212G1, the mirror 212R1, a mirror 212R2, and the mirror 212B1 as the mirror 212. The mirror 212G1 is disposed on the light extraction surface D side of the light emitting element array 30G. The mirror 212G1 reflects the green light WG that is emitted from the light emitting element array 30G and that travels in the +Z direction. The green light WG reflected on the mirror 212G1 travels in the +X direction. The mirror 212B1 is disposed on the light extraction surface D side of the light emitting element array 30B. The mirror 212B1 reflects the blue light WB that is emitted from the light emitting element array 30B and that travels in the +Z direction. The blue light WB reflected on the mirror 212B1 travels in the −X direction. The prism 211 is provided at a position between the mirror 212G1 and the mirror 212B1. The prism 211 is a cross prism which changes the traveling direction (−X direction) of the blue light WB to the +Z direction as depicted in FIG. 23A and FIG. 23B. Moreover, the cross prism changes the traveling direction (+X direction) of the green light WG to the +Z direction as depicted in FIG. 23A and FIG. 23B. In FIG. 23A and FIG. 23B, a round mark that has a dot at the center of the mark and is given on a solid line representing a traveling route of the blue light WB indicates that the light travels from the back of the sheet of the figure toward the front. A round mark that has a cross inside the mark and is given on a solid line representing a traveling route of the green light WG indicates that the light travels from the front of the sheet of the figure toward the back. These round marks are also applied to traveling routes of the red light, the blue light, and the green light illustrated in FIGS. 23 to 26.

The mirror 212R2 is provided immediately above the prism 211 in the optical system 210. Moreover, the mirror 212R1 is disposed on the light extraction surface D side of the light emitting element array 30R. The mirror 212R1 reflects the red light WR traveling in the +Z direction from the light extraction surface D of the light emitting element array 30R, such that the red light WR travels in a direction toward the mirror 212R2. In the example depicted in FIG. 23A and FIG. 23B, the positions of the mirrors 212R1 and 212R2 in the Z-axis direction are aligned at substantially the same position. An adjuster for adjusting the positions of the mirrors 212R1 and 212R2 may be provided between the mirror 212R1 and the light emitting element array 30R. According to the example in FIG. 23A and FIG. 23B, the red light WR is reflected on the mirror 212R1, and travels in the −Y direction. The red light WR traveling in −Y direction is reflected on the mirror 212R2. At this time, the traveling direction of the red light WR is switched to the +Z direction. The blue light WB and the green light WG pass through the prism 211 and then the mirror 212R2 in the +Z direction. At this time, the red light WR, the blue light WB, and the green light WG traveling in the +Z direction join at the position of the mirror 212R2. The light produced by combining the red light WR, the blue light WB, and the green light WG (combined light) is emitted in a direction away from the first surface side (the +Z direction).

### Modification 3

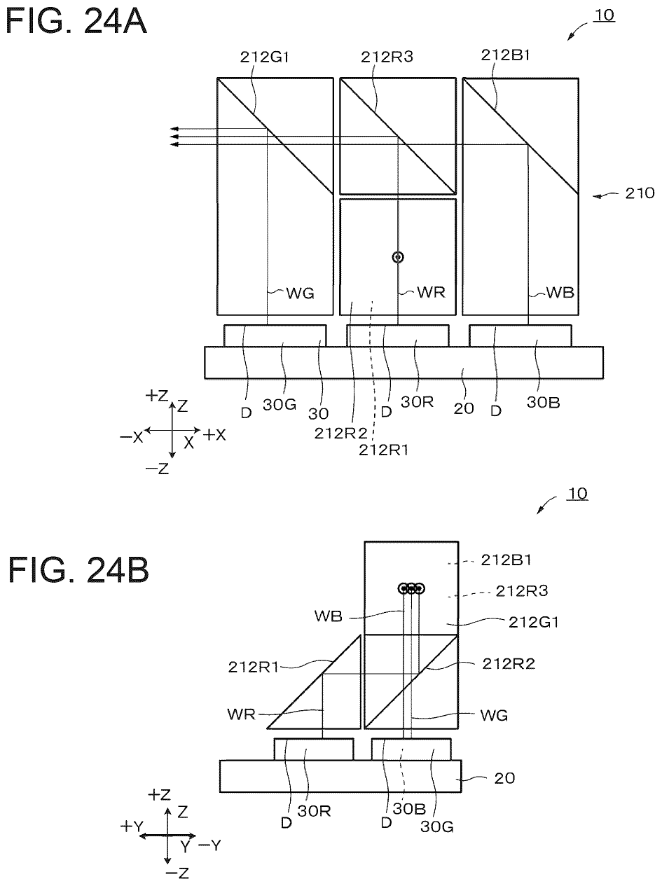

As in modification 2 of the fifth embodiment described above, the light emitting device 10 according to modification 3 of the fifth embodiment has a V-shaped arrangement pattern for the layout of the light emitting element arrays 30, and also includes the optical system 210 disposed above the light emitting element arrays 30 as depicted in FIG. 24A and FIG. 24B. However, the optical system 210 is configured to emit combined light in a planar direction toward the light extraction surface D (the X-axis direction in FIG. 24A). FIG. 24A is a diagram for schematically explaining a state of the light emitting device 10 which has a visual line direction of the arrow E1 in FIG. 11B, and corresponds to a front diagram schematically depicting the light emitting device 10 according to modification 3 of the fifth embodiment. FIG. 24B is a diagram for schematically explaining a state of the light emitting device 10 which has a visual line direction of the arrow E2 in FIG. 11B, and corresponds to a side diagram schematically depicting the light emitting device 10 according to modification 3 of the fifth embodiment.

### (Optical System)

The optical system 210 includes the mirror 212G1, the mirror 212R1, the mirror 212R2, a mirror 212R3, and the mirror 212B1 as five mirrors of the mirror 212. The mirror 212R1 is disposed on the light extraction surface D side of the light emitting element array 30R. The mirror 212R1 reflects the red light WR that is emitted from the light emitting element array 30 and that travels in the +Z direction. At this time, the traveling direction of the red light WR is switched to the −Y direction. The mirror 212R2 is disposed in the traveling direction of the red light WR traveling in the −Y direction. The red light WR traveling in −Y direction is reflected on the mirror 212R2, and caused to travel in the +Z direction. The mirror 212R3 is disposed above (on the +Z side of) the mirror 212R2. The red light WR that has been reflected on the mirror 212R2 is reflected on the mirror 212R3. At this time, the traveling direction of the red light is switched from the +Z direction to the −X direction. In addition, the mirror 212G1 is disposed above (on the +Z side of) the light emitting element array 30G. The mirror 212B1 is disposed above (on the +Z side of) the light emitting element array 30B. The mirror 212G1 reflects the green light WG that is emitted from the light emitting element array 30G and that travels in the +Z direction. At this time, the traveling direction of the green light WG is switched to the −X direction. The mirror 212B1 reflects the blue light WB that is emitted from the light emitting element array 30B and that travels in the +Z direction. At this time, the traveling direction of the blue light WB is switched to the −X direction. The positions of the mirrors 212G1 and 212B1 in the Z-axis direction are aligned with the position of the mirror 212R3. In addition, the mirrors 212G1, 212B1, and 212R3 are arranged in a line in the X-axis direction. Accordingly, the blue light WB is reflected on the mirror 212B1, and then passes through the mirrors 212R3 and 212G1 in the −X direction. The red light WR is reflected on the mirror 212R3, and then passes through the mirror 212G in the −X direction. Thereafter, the green light WG reflected on the mirror 212G1, the blue light WB reflected on the mirror 212B1, and the red light WR reflected on the mirror 212R3 join in a traveling state in the −X direction, and light produced by combining the red light WR, the blue light WB, and the green light WG (combined light) is emitted in the planar direction of the light extraction surface D (the −X direction).

### Modification 4

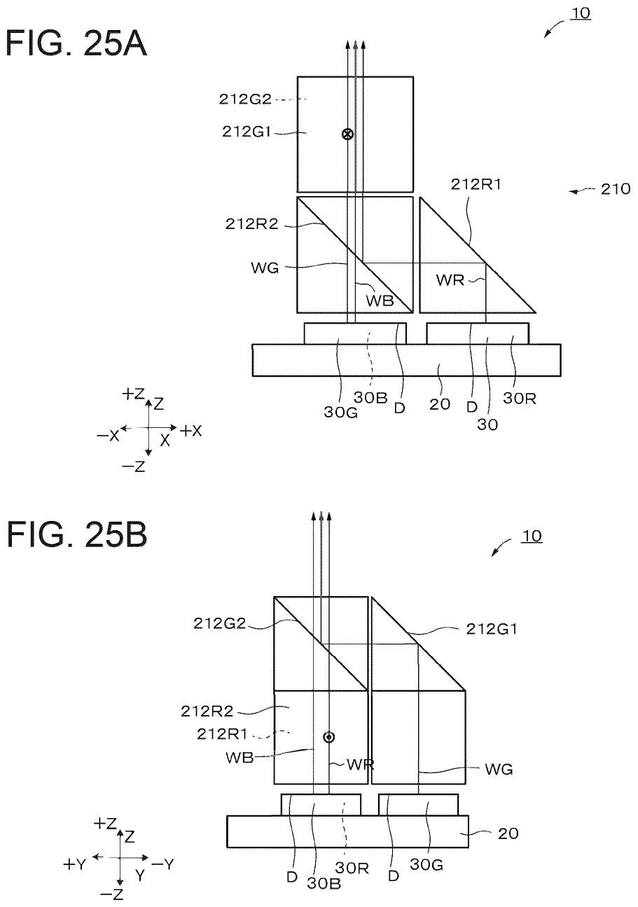

The light emitting device 10 according to modification 4 of the fifth embodiment has an L-shaped arrangement pattern for the layout of the light emitting element arrays 30 as depicted in FIG. 11A, and includes the optical system 210 above the light emitting element arrays 30 as depicted in FIG. 25A and FIG. 25B. The optical system 210 is configured to emit combined light in a direction away from the light extraction surface D. FIG. 25A is a diagram for schematically explaining a state of the light emitting device 10 which has a visual line direction of the arrow E1 in FIG. 11A, and corresponds to a front diagram schematically depicting the light emitting device 10 according to modification 4 of the fifth embodiment. FIG. 25B is a diagram for schematically explaining a state of the light emitting device 10 which has a visual line direction of the arrow E2 in FIG. 11A, and corresponds to a side diagram schematically depicting the light emitting device 10 according to modification 4 of the fifth embodiment.

### (Optical System)

The optical system 210 includes the mirror 212R1, the mirror 212R2, the mirror 212G1, and a mirror 212G2 as four mirrors of the mirror 212. The mirror 212R1 is disposed on the light extraction surface D side of the light emitting element array 30R. The mirror 212R1 reflects the red light WR that is generated from the light emitting element array 30R and that travels in the +Z direction. At this time, the traveling direction of the red light WR is switched from the +Z direction to the −X direction. The mirror 212R2 is disposed in the traveling direction of the red light WR traveling in the −X direction and on the light extraction surface D side of the light emitting element array 30B. The red light WR that has been reflected on the mirror 212R1 is reflected on the mirror 212R2. At this time, the traveling direction of the red light WR is switched from the −X direction to the +Z direction. Note that the mirror 212R2 allows the blue light WB to pass through it. The mirror 212G2 is disposed above (on the +Z side of) the mirror 212R2. The mirror 212G2 reflects the green light WG traveling in the +Y direction. The mirror 212G2 allows the blue light WB and the red light WR to pass through it.

In addition, the mirrors 212G1 is disposed on the light extraction surface D side of the light emitting element array 30G. The mirror 212G1 reflects the green light WG that is emitted from the light emitting element array 30G and that travels in the +Z direction, such that the green light WG travels toward the mirror 212G2. In FIG. 25A and FIG. 25B, the position of the mirror 212G1 in the Z-axis direction is aligned with the position of the mirror 212G2, and the mirrors 212G1 and 212G2 are arranged in a line in the Y-axis direction. The mirror 212G1 switches the traveling direction of the green light WG from the +Z direction to the +Y direction. Thereafter, the green light WG traveling in the +Y direction is reflected on the mirror 212G2. At this time, the traveling direction of the green light WG is switched from the +Y direction to the +Z direction. The green light WG, the blue light WB, and the red light WR join in a traveling state in the +Z direction at the position of the mirror 212G2. The light produced by combining the red light WR, the blue light WB, and the green light WG (combined light) is emitted in a direction away from the first surface side (the +Z direction).

### Modification 5

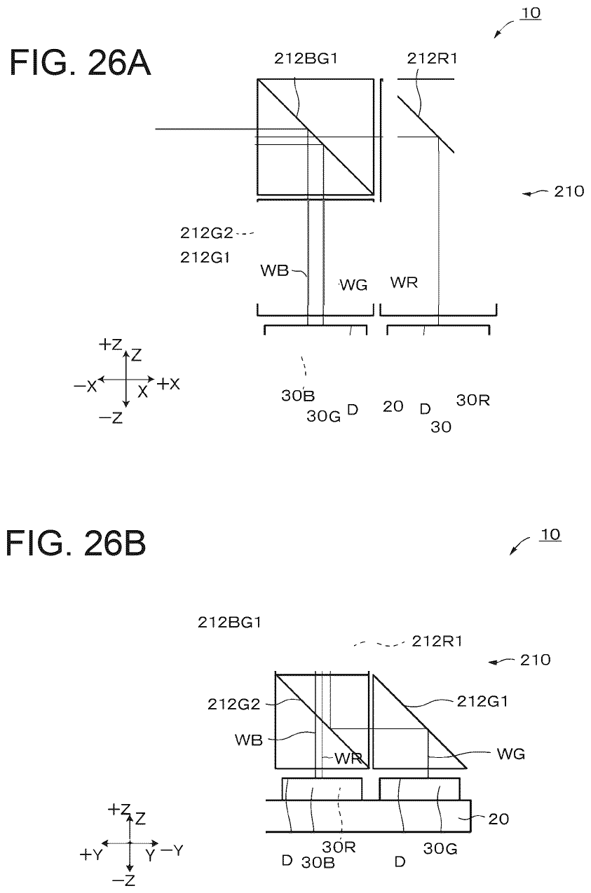

As in modification 4 of the fifth embodiment, the light emitting device according to modification 5 of the fifth embodiment has an L-shaped arrangement pattern for the layout of the light emitting element arrays 30, and also includes the optical system 210 disposed above the light emitting element arrays 30 as depicted in FIG. 26A and FIG. 26B. The optical system 210 is configured to emit combined light in a planar direction toward the light extraction surface D (the X-axis direction in FIG. 26A). FIG. 26A is a diagram for schematically explaining a state of the light emitting device 10 which has a visual line direction of the arrow E1 in FIG. 11A, and corresponds to a front diagram schematically depicting the light emitting device 10 according to modification 5 of the fifth embodiment. FIG. 26B is a diagram for schematically explaining a state of the light emitting device 10 which has a visual line direction of the arrow E2 in FIG. 11A, and corresponds to a side diagram schematically depicting the light emitting device 10 according to modification 5 of the fifth embodiment.

### (Optical System)

The optical system 210 includes the mirror 212R1, a mirror 212BG1, the mirror 212G1, and the mirror 212G2 as four mirrors of the mirror 212. The mirrors 212G1 is disposed on the light extraction surface D side of the light emitting element array 30G. The mirror 212G1 reflects the green light WG that is emitted from the light emitting element array 30G and that travels in the +Z-axis direction. At this time, the traveling direction of the green light WG is switched from the +Z direction to the +Y direction. The mirror 212G2 is disposed in the traveling direction of the green light WG traveling in the +Y direction and on the light extraction surface D side of the light emitting element array 30B. The green light WG traveling in the +Y direction is reflected on the mirror 212G2. At this time, the traveling direction of the green light WG is switched from the +Y direction to the +Z direction. Note that the mirror 212G2 allows the blue light WB emitted in the +Z direction from the light emitting element array 30B to pass through it. The mirror 212BG1 is disposed on the side immediately above (the +Z side of) the mirror 212G2. The mirror 212BG1 reflects the blue light WB and the green light WG. Accordingly, the green light WG that has been reflected on the mirror 212G2 and that travels in the +Z direction and the blue light WB that has been passed through the mirror 212G2 are reflected on the mirror 212BG1. At this time, each of the traveling directions of the green light WG and the blue light WB is switched from the +Z direction to the −X direction. Note that the mirror 212BG1 allows the red light WR to pass through it.

Meanwhile, the mirror 212R1 is disposed on the light extraction surface D side of the light emitting element array 30R. The mirror 212R1 reflects the red light WR that is emitted from the light emitting element array 30R and that travels in the +Z direction. At this time, the traveling direction of the red light WR is switched from the +Z direction to the −X direction. In the example in FIG. 26A and FIG. 26B, the position of the mirror 212R1 in the Z-axis direction is aligned with the position of the mirror 212BG1, and the mirrors 212R1 and 212BG1 are arranged in a line in the X-axis direction. The red light WR reflected on the mirror 212R1 travels in the −X direction toward the mirror 212BG1. Thereafter, the red light WR passes through the mirror 212BG1 as described above.

As a result, the red light WR, the blue light WB, and the green light WG join at the position of the mirror 212BG1 in the optical system 210 while facing in the −X direction, and light produced by combining the red light WR, the blue light WB, and the green light WG (combined light) is emitted in the planar direction of the light extraction surface D (the −X direction).

### 6 Application Examples

For example, each of the light emitting devices 10 according to the first to fifth embodiments and the modifications thereof described above is applicable to a device, an apparatus, a component, or the like which transmits and receives light signals. Specifically, the light emitting device 10 is applicable to a photo-coupler, a drum photosensitive type printer light source, a scanner light source, an optical fiber light source, an optical disk light source, an optical remote controller, an optical measuring device, or the like. In addition, examples of the light emitting device include a headlight of a vehicle, an image display device, a backlight, a lighting apparatus, or the like. The examples of the device including the light emitting element arrays also include a display unit provided on a tiling-type display device containing an array of multiple display units.

More specifically, each of the light emitting devices 10 according to the first to fifth embodiments and the modifications thereof described above is also applicable to various types of electronic apparatuses. Specific examples of the electronic apparatus include a projection device, a personal computer, a mobile device, a cellular phone, a tablet-type computer, an imaging device, a game console, an industrial device, a robot, and the like. However, the electronic apparatus is not limited to these examples. For example, the light emitting device 10 according to the fifth embodiment may be used as a projection device. A specific example of the electronic apparatus to which the light emitting device 10 is applied will be further explained hereinafter.

### Specific Example

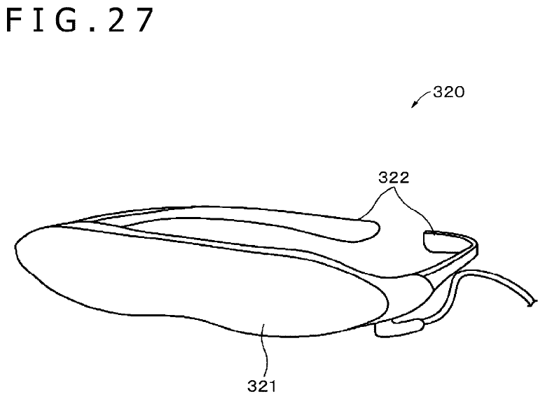

FIG. 27 depicts an example of an external appearance of a head-mounted display 320. For example, the head-mounted display 320 has ear hooks 322 that is disposed on both sides of a display unit 321 having a glass shape and that is for attachment to the head of a user. For example, a display device including the light emitting device 10 according to any one of the first to fifth embodiments and the modifications thereof described above is applicable to the display unit 321. The head-mounted display 320 thus configured is available as VR glasses, AR glasses, or the like, for example. The head-mounted display 320 incorporating the light emitting device 10 as described above can achieve reduction of stray light and power consumption.

While the specific examples of the embodiments according to the present disclosure and the modifications and the manufacturing method thereof have been described above, the present disclosure is not limited to the examples of the embodiments, the modifications, and the manufacturing methods described above. Various types of modifications can be made on the basis of technical ideas of the present disclosure.

For example, configurations, methods, steps, shapes, materials, numerical values, and the like included in the examples of the first to fifth embodiments and the modifications and manufacturing methods thereof described above are presented only by way of example. configurations, methods, steps, shapes, materials, numerical values, and the like different from those described above may be used as necessary.

Moreover, the configurations, methods, steps, shapes, materials, numerical values, and the like included in the first to fifth embodiments and the modifications and manufacturing methods thereof described above by way of example can be combined without departing from the scope of the subject matters of the present disclosure.

Only one type of the materials included in the first to fifth embodiments and the modifications and the manufacturing methods thereof described above by way of example can be used, or two or more types of these materials can be combined unless otherwise specified. In addition, note that it is not intended that interpretation of the contents of the present disclosure be limited by the advantageous effects presented in the present disclosure by way of example.

The present disclosure can also adopt the following configurations.

(1)

A light emitting device including:
multiple light emitting element arrays each of which includes multiple light emitting elements; and
a main substrate that includes a drive circuit,
in which the multiple light emitting element arrays are provided on the same main substrate.
   (2)

The light emitting device according to (1) above,
in which the light emitting elements provided on at least one of the light emitting element arrays are LED elements.
   (3)

The light emitting device according to (1) above,
in which the light emitting elements provided on at least one of the light emitting element arrays are OLED elements.
   (4)

The light emitting device according to (1) above,
in which the light emitting elements provided on at least one of the light emitting element arrays are quantum dot light emitting elements.
   (5)

The light emitting device according to (1) above,
in which each of the light emitting elements provided on at least two of the light emitting element arrays is selected from a group including an LED element, an OLED element, and a quantum dot light emitting element, and the light emitting elements provided on one of the at least two of the light emitting element arrays are elements of a type different from that of the light emitting elements provided on another of the at least two of the light emitting element arrays.
   (6)

The light emitting device according to any one of (1) to (5) above,
in which the light emitting elements provided on one of at least two of the light emitting element arrays has a size different from that of the light emitting elements provided on another of the at least two of the light emitting element arrays.
   (7)

The light emitting device according to any one of (1) to (6) above,
in which the multiple light emitting elements included in each of the light emitting element arrays are two-dimensionally arranged in a first direction and a second direction crossing each other at right angles, and are provided such that the number of the light emitting elements per unit length in the first direction and the number of the light emitting elements per unit length in the second direction are different from each other.
   (8)

The light emitting device according to any one of (1) to (7) above,
in which the multiple light emitting element arrays include three types of light emitting element arrays having emission colors different from each other.
   (9)

The light emitting device according to any one of (1) to (8) above,
in which the multiple light emitting element arrays include a first light emitting element array having a first emission color and a second light emitting element array having multiple emission colors different from the first color.
   (10)

The light emitting device according to any one of (1) to (9) above,
in which the light emitting element arrays have a layout of any pattern selected from a one-line type, an L-shaped type, and a V-shaped type.
   (11)

The light emitting device according to (2) above and any one of (6) to (10) above dependent on (2),
in which at least one of the light emitting element arrays is a sub-substrate that includes the multiple light emitting elements and is different from the main substrate.
   (12)

The light emitting device according to any one of (1) to (11) above,
in which each of the multiple light emitting element arrays has a light extraction surface, and
an optical system that combines rays of light generated from the light extraction surfaces of the respective light emitting element arrays is provided above the light extraction surfaces.
   (13)

An electronic apparatus including:
the light emitting device according to any one of (1) to (12) above.

### REFERENCE SIGNS LIST

10: Light emitting device
12: Vertical scanning circuit
13: Horizontal scanning circuit
14: Pixel unit
15: Pixel circuit
20: Drive substrate
21: Substrate
30: Light emitting element array
40: Light emitting element
41: First electrode
42: Second electrode
43: Laminated structure body
44: First compound semiconductor layer
45: Second compound semiconductor layer
46: Light emitting layer
50: LED element
51: Protection layer
52: Metal layer
54: Quantum dot layer
100: OLED element
150: Quantum dot light emitting element
201: Sub-pixel
210: Optical system
211: Prism
212: Mirror
320: Head-mounted display
321: Display unit
322: Ear hook
D: Light extraction surface
WB: Blue light
WG: Green light
WR: Red light

What is claimed is:

1. A light emitting device, comprising:
multiple light emitting element arrays each of which includes multiple light emitting elements; and
a main substrate that includes a drive circuit,
wherein the multiple light emitting element arrays are provided on the same main substrate.

2. The light emitting device according to claim 1,
wherein the light emitting elements provided on at least one of the light emitting element arrays are LED elements.

3. The light emitting device according to claim 1,
wherein the light emitting elements provided on at least one of the light emitting element arrays are OLED elements.

4. The light emitting device according to claim 1,
wherein the light emitting elements provided on at least one of the light emitting element arrays are light emitting elements each of which includes a quantum dot.

5. The light emitting device according to claim 1,
wherein each of the light emitting elements provided on at least two of the light emitting element arrays is selected from a group including an LED element, an OLED element, and a quantum dot light emitting element, and the light emitting elements provided on one of the at least two of the light emitting element arrays are elements of a type different from that of the light emitting elements provided on another of the at least two of the light emitting element arrays.

6. The light emitting device according to claim 1,
wherein the light emitting elements provided on one of at least two of the light emitting element arrays has a size different from that of the light emitting elements provided on another of the at least two of the light emitting element arrays.

7. The light emitting device according to claim 1,
wherein the multiple light emitting elements included in each of the light emitting element arrays are two-dimensionally arranged in a first direction and a second direction crossing each other at right angles, and are provided such that the number of the light emitting elements per unit length in the first direction and the number of the light emitting elements per unit length in the second direction are different from each other.

8. The light emitting device according to claim 1,
wherein the multiple light emitting element arrays include three types of light emitting element arrays having emission colors different from each other.

9. The light emitting device according to claim 1,
wherein the multiple light emitting element arrays include a first light emitting element array having a first emission color and a second light emitting element array having multiple emission colors different from the first color.

10. The light emitting device according to claim 1,
wherein the light emitting element arrays have a layout of any pattern selected from a one-line type, an L-shaped type, and a V-shaped type.

11. The light emitting device according to claim 2,
wherein at least one of the light emitting element arrays is a sub-substrate that includes the multiple light emitting elements and is different from the main substrate.

12. The light emitting device according to claim 1,
wherein each of the multiple light emitting element arrays has a light extraction surface, and
an optical system that combines rays of light generated from the light extraction surfaces of the respective light emitting element arrays is provided above the light extraction surfaces.

13. An electronic apparatus comprising:
the light emitting device according to claim 1.
